(19) United States
(12) Patent Application Publication
(10) Pub. No.: US 2026/0056474 A1
(43) Pub. Date: Feb. 26, 2026

(54) METHOD FOR ADJUSTING THE TELECENTRICITY IN A PROJECTION EXPOSURE SYSTEM FOR MICROLITHOGRAPHY

(71) Applicant: Carl Zeiss SMT GmbH, Oberkochen (DE)

(72) Inventors: Jan Biller, Veldhoven (NL); Dirk Petrus Josephus Van Leuken, Veldhoven (NL); Ijen Laurens Van Mil, Veldhoven (NL); Ruirt Willem Bosma, Veldhoven (NL); Johannes Jacobus Matheus Baselmans, Veldhoven (NL); Stig Bieling, Oberkochen (DE)

(21) Appl. No.: 19/374,664

(22) Filed: Oct. 30, 2025

Related U.S. Application Data
(63) Continuation of application No. PCT/EP2024/062067, filed on May 2, 2024.

(30) Foreign Application Priority Data
May 4, 2023 (DE) 10 2023 204 114.6
Jan. 30, 2024 (DE) 10 2024 200 820.6

(51) Int. Cl. G03F 7/00

(52) U.S. Cl. CPC G03F 7/70266; G03F 7/70191

(57) ABSTRACT

A method for adjusting the telecentricity in a projection exposure system for microlithography comprises: providing a projection exposure system having an illumination system, a projection system, a mask, a radiation source and/or an aperture stop; and adjusting the telecentricity in the projection exposure system, which comprises adjusting a telecentricity of the illumination system.

### CROSS-REFERENCE TO RELATED APPLICATIONS

The present application is a continuation of, and claims benefit under 35 USC 120 to, international application No. PCT/EP2024/062067, filed May 2, 2024, which claims benefit under 35 USC 119 of German Application No. 10 2023 204 114.6, filed May 4, 2023, and German Application No. 10 2024 200 820.6, filed Jan. 30, 2024. The entire disclosure of each of these applications is incorporated by reference herein.

### FIELD

The present disclosure relates to a method for adjusting the telecentricity in a projection exposure system for microlithography. In addition, the present disclosure relates to a projection exposure system for microlithography.

### BACKGROUND

Projection exposure systems for microlithographic and methods using such projection exposure systems are used predominantly for producing semiconductor components and other finely patterned components. These methods involve the use of masks (photomasks, reticles) or other patterning mechanisms that bear or form the pattern of a structure to be imaged, e.g. a line pattern of a layer of a semiconductor component. The pattern is positioned in a projection exposure system in the optical path between an illumination system and a projection system such that the pattern lies in the region of the object plane of the projection system. A substrate for microlithography to be exposed, for example a silicon wafer coated with a radiation-sensitive layer (resist, photoresist), is held in such a way that a radiation-sensitive layer provided on the substrate is arranged in the region of an image plane of the projection system, the image plane being optically conjugate with respect to the object plane. During an exposure process, the pattern is illuminated with the aid of the illumination system, which, using radiation provided by a radiation source, shapes radiation which is directed onto the pattern of the mask. The radiation altered by the pattern passes through the projection system, which projects, or images, the pattern onto the substrate to be exposed.

The pattern projected on the radiation-sensitive layer contributes to creating a profile in the radiation-sensitive layer. This profile comprises at least one upper surface and at least one sidewall extending from the upper surface towards the substrate or another layer provided between the substrate and the radiation-sensitive layer. The angle of the sidewall, also called sidewall angle, relative to the substrate and/or another layer provided between the substrate and the radiation-sensitive layer is a relevant dimension for certain applications in microlithography. For example a staircase profile created in the radiation-sensitive layer is used in the production of 3D NAND memory, wherein a profile used in the layout of the staircase profile comprises a pair of, for example opposed, sidewalls. The sidewalls of the pair of sidewalls are intended to have the same sidewall angle but with opposite sign. In case, however, the sidewall angles between the sidewalls of the pair of sidewalls deviate from each other, one calls it a sidewall angle asymmetry. This sidewall angle asymmetry can be the consequence of variations of the telecentricity in the projection exposure system and/or variations in the thickness of the radiation-sensitive layer, for example. The slope of the radiation-sensitive layer and/or the laser linewidth of the radiation can also impact the sidewall angle asymmetry. In the production of 3D NAND memory a sidewall angle of the profile deviating from the intended sidewall angle, for example a sidewall angle asymmetry, can influence the width and the position of the so called contact landing pads of the 3D NAND memory. Generally, the higher the deviation of the sidewall angle from the intended sidewall angle and/or the bigger the sidewall angle asymmetry the lower the yield during the 3D NAND memory production.

In general, the described sidewall asymmetry can currently not be corrected for easily. Generally, adjusting the focus of projection exposure system or the dose of the radiation provided and guided by the projection exposure system does not only impact the sidewall angle but also the critical dimensions of the profile in the radiation-sensitive layer in a possible non-linear behavior. In general, adjusting the coating of the radiation-sensitive layer onto the substrate on the other hand is rather labor intensive and has limited temporal and spatial adjustability.

### SUMMARY

One favorable option to reduce the deviation of a sidewall angle of a profile created in the radiation-sensitive layer from the intended sidewall angle, for example a sidewall angle asymmetry, is to adjust the telecentricity in the projection exposure system.

The present disclosure seeks to provide a method and a system that can reduce the deviation of a sidewall angle of a profile to be created in the radiation-sensitive layer from the intended sidewall angle, for example to provide a method and system that can reduce sidewall angle asymmetry.

The disclosure provides a method for adjusting the telecentricity in a projection exposure system for microlithography which comprises step a): providing a projection exposure system, wherein the projection exposure system has an illumination system, a projection system, a mask, a radiation source and/or an aperture stop, wherein the projection exposure system is configured to guide radiation. The illumination system can comprise a radiation 15 source and/or an illumination optic. The illumination system, for example the illumination optic, is configured for illuminating an object field in an object plane of the projection system, for example an object plane of the projection optic. A mask arranged in the object plane, for example an object field, of the projections system can be illuminated by the illumination system, for example the illumination optic. The illumination system, for example the illumination optic, can comprise at least one optical element, for example at least one lens and/or at least one mirror. The radiation source can also be provided as a module separate from the illumination system. The projection system can comprise a projection optic. The projection system is configured for imaging the object field of the projection system, for example the object field of the projection optic, into an image field in an image plane of the projection system, for example of the projection optic. The image plane can run parallel to the object plane of the projection system, however, an angle other than 0° between the object plane and the image plane of the projection system is also possible. The projection system, such as the projection optic, can comprise at least one optical element, for example at least one lens and/or at least one mirror. The mask comprises a pattern of a structure to be imaged. The mask can be arranged in the object plane, such as the object field, of the projection system, for example of the projection optic and/or or the image plane, optionally the image field, of the illumination system, for example of the illumination optic. The mask can be held by a mask holder, wherein the mask holder can be displaceable by a mask displacement drive, for example in a scan direction. The radiation source can provide radiation which is used for shaping radiation which can be guided by the projection exposure system. The radiation source can be a DUV radiation source emitting DUV radiation and/or a EUV radiation source emitting EUV radiation. The aperture stop can be designed as a diaphragm and/or is arranged in the projection system, such as in the projection optic. The projection exposure system can alternatively or in addition comprise a substrate holder for holding a substrate for microlithography. The substrate holder can be displaceable by a substrate displacement drive. The projection exposure system can be configured to provide and/or guide radiation. For example, the projection exposure system is configured to guide the radiation through the illumination system, through the mask, through the projection system, to a substrate holder and/or to a substrate.

Moreover, for adjusting the telecentricity in a projection exposure system for microlithography, the method comprises step b): adjusting the telecentricity in the projection exposure system. Optionally, in step b), the telecentricity is adjusted by adjusting the optical path of the projection exposure system, by adjusting the optical axis of the projection exposure system and/or by adjusting radiation guided by the projection exposure system. By adjusting the telecentricity, radiation guided by a projection exposure system can impinge the mask and/or the substrate in a predetermined orientation, for example at least one chief ray of the radiation can run substantially parallel to the optical axis when entering and/or exiting the mask, which contributes to a more accurate alteration of the radiation by the pattern of the mask and/or to a more accurate imaging of the pattern onto the substrate. The telecentricity can be adjusted by adjusting the optical path of the projection exposure system. The optical path of the exposure system is the path defined by the radiation which can be transmitted from the radiation source to the image plane of the projection system, for example to the substrate provided in the image plane. The optical path can, for example, be adjusted by displacing and/or altering the optical path, optionally by displacing and/or altering at least on optical element provided in the optical path. Alternatively or in addition the telecentricity can be adjusted by adjusting the optical axis of the projection exposure system. The optical axis can, for example, be adjusted by displacing and/or altering the optical axis. Alternatively or in addition the telecentricity can be adjusted by adjusting radiation guided by the projection exposure system. The radiation can for example be adjusted by displacing and/or altering the radiation, optionally by providing and/or adjusting a filter element provided in the optical path. The telecentricity can be adjusted by adjusting the optical path and/or optical axis of the illumination system and/or of the projection system. Adjusting the telecentricity at the respective sections of the projection exposure system can contribute to achieving telecentric radiation at the desired locations. By adjusting the telecentricity in the projection exposure system it is for example envisaged that the radiation impinging the mask, exiting the mask and/or impinging the wafer is telecentric.

Furthermore, it can be provided that in step b) the telecentricity is adjusted by applying at least one aberration to the radiation guided by the projection exposure system. Here it can be provided for that the telecentricity is adjusted in the projection optic (i.e., projection objective) of the projection exposure system and/or that the telecentricity is adjusted by applying the at least one aberration in the projection optic of the projection exposure system. In this case it can be desirable to apply the aberration along the optical path of the projection exposure system after (i.e., downstream of) the mask, before (i.e., upstream of) the image plane of the projection system and/or before (i.e., upstream of) the substrate for microlithography, for example wafer. Generation of the aberration can for example be achieved by adjusting at least one optical element, such as the first optical element, the second optical element and/or the third optical element, of the projection exposure system. For example, the optical element can be adjusted by a deformation of the optical element, for example by using one or more actuators to exert force on one or more sides of the optical element and/or by using one or more heating elements to heat one or more selected regions of the optical element. Alternative or in addition the optical element can be adjusted by adjusting the position and/or inclination of the optical element and/or by applying strain to the optical element. The strain can for example be applied to the optical element by bending the optical element, optionally at several positions of the optical element, for example at the edge of the optical element, and/or opposing sides of the optical element. The amplitude of at least one aberration applied in step b) can be in the range of at least 0.1 nm, such as at least 1 nm, for example at least 10 nm, for example at least 100 nm and/or at most 400 nm, for example at most 300 nm, for example at most 200 nm, for example at most 150 nm. Hereby a sufficient adjustment of the telecentricity can be achieved without negatively influencing the image quality too much. The at least one aberration here for example refers to at least one aberration defined as at least one Zernike polynomial (i.e., Zernike coefficient) according to the Fringe indexing scheme. The amplitude of the at least one aberration can apply for a wavelength of the radiation, for example the radiation guided by the projection exposure system, of at least 5 nm and/or at most 500 nm, for example at least 100 nm and/or at most 350 nm, for example 248 nm, and/or for a numerical aperture (NA) of at least 0.45, for example at least 0.5, for example at least 0.55 and/or at most 0.9, for example at most 0.85, for example at most 0.8. Alternative or in addition, the at least one aberration, such as the amplitude of the at least one aberration, can apply for the profile of at least one Zernike polynomial over a plurality of field points which describe the at least one aberration and which, for its part, is determined at various field points in the scanner slit of the projection optic. The scanner slit is the section of the image field of the projection optic, which is imaged at once, for example when the projection exposure system is used as a scanner. The scanner slit can be a rectangular section of the image field of the projection optic. The amplitude of at least one aberration can for example be the amplitude of the offset (i.e., tunable component), tilt (i.e., centrable component) and/or 3^{rd} order component of the profile of the at least one aberration, for example profile of the respective Zernike polynomial, over a plurality of field points.

With regard to the telecentricity it is to be kept in mind that even after adjusting the telecentricity the radiation in reality may not be absolutely telecentric, for example the radiation impinging the mask, exiting the mask and/or impinging the wafer will not be absolutely telecentric. Optionally, every cone of the radiation will have its own angle with respect to the optical axis, which angle slightly deviates from a course parallel to the optical axis. In view of this, it is for example envisaged that by adjusting the telecentricity the deviation of the angle of the radiation, such as the angle of least one chief ray of the radiation, guided by the projection exposure system with regard to the optical axis of the projection exposure system is set, for example in and/or adjacent to the image plane of the illumination system, the object plane of the projection system and/or the image plane of the projection system, to an amount of no more than ±15 mrad, such as no more than ±10 mrad, for example no more than ±5 mrad, for example no more than ±1 mrad, for example no more than ±0.5 mrad, for example no more than ±0.25 mrad.

Adjusting the telecentricity in the projection exposure means that an adjustment is made in and/or to the projection exposure system to substantially achieve telecentricity, for example telecentric radiation, at least in sections in the projection exposure system, for example along the optical path and/or optical axis of the projection exposure system. It is not necessary to achieve telecentricity, for example telecentric radiation, in every section of the projection exposure system. Optionally, it is envisaged that by adjusting the telecentricity in the projection exposure system telecentricity, for example telecentric radiation, in and/or adjacent to the image plane of the illumination system, the object plane of the projection system and/or the image plane of the projection system is achieved.

The method can also comprise the step c): determining at least one critical dimension, at least one sidewall angle and/or at least one sidewall angle asymmetry of a profile created in a radiation-sensitive layer provided on a substrate, for example before, during and/or after adjusting the telecentricity in the projection exposure system in step b). Optionally, in step c) at least one critical dimension, at least one sidewall angle and/or at least one sidewall angle asymmetry of a profile created in a radiation-sensitive layer provided on a substrate is determined by measuring at least in sections the profile created in the radiation-sensitive layer provided on the substrate. Such measurements are also called (photo-) resist measurements. Moreover, the telecentricity in the projection exposure system can be adjusted in step b) based on the at least one critical dimension, at least one sidewall angle and/or at least one sidewall angle asymmetry of a profile created in a radiation-sensitive layer provided on a substrate determined in step c). Step c) can take place before, during and/or after step b).

The term “critical dimension” is a technical term well known in microlithography and describes for example a dimension that allows, for example systematic, conclusions to be made about the quality of machining of a process step, for example a line width or a diameter of a contact hole.

The method can also comprise the step d): creating a profile in a radiation-sensitive layer provided on a substrate. Step d) can comprise exposing at least a part of a radiation-sensitive layer provided on a substrate to radiation provided and/or guided by the projection exposure system, developing at least a part of a radiation-sensitive layer and/or removing at least a part of a radiation-sensitive layer. The step d) can take place before, during and/or after step b) and/or step c).

Step a) can comprise providing a second projection exposure system. The second exposure system can be designed substantially identical to the initially provided projection exposure system. Optionally, in step b) the telecentricity in the second projection exposure system is adjusted substantially in the same way as the telecentricity in the initially provided projection exposure system.

According to a first embodiment, in step b) the telecentricity is adjusted on the object side of the illumination system, for example in and/or adjacent to the object plane of the illumination system, in step b) the telecentricity is adjusted on the image side of the illumination system, for example in and/or adjacent to the image plane of the illumination system, in step b) the telecentricity is adjusted on the object side of the projection system, for example in and/or adjacent to the object plane of the projection system and/or in step b) the telecentricity is adjusted on the image side of the projection system, for example in and/or adjacent to the image plane of the projection system. Thereby telecentricity can substantially achieved at least in sections on the respective side of the illumination system, which contributes to a targeted adjustment of the telecentricity. For instance, when the telecentricity is adjusted in and/or adjacent to the image plane of the illumination system or in and/or adjacent to the object plane of the projection system radiation guided by the a projection exposure can impinge the mask in a predetermined orientation, for example at least one chief ray of the radiation can run substantially parallel to the optical axis when entering and/or exiting the mask, thereby contributing to a more accurate alteration of the radiation by the pattern of the mask. This can contribute in turn to reducing deviations of a sidewall angle of a profile to be created in a radiation-sensitive layer from the intended sidewall angle. Moreover, when the telecentricity is adjusted in and/or adjacent to the image plane of the projection system, the radiation guided by the projection exposure system and altered by the pattern of the mask can impinge the radiation-sensitive layer provided on the substrate in a predetermined orientation, for example at least one chief ray of the radiation can run substantially parallel to the optical axis when impinging the radiation-sensitive layer, thereby contributing to a more accurate imaging of the pattern onto the substrate. Alternatively or in addition the telecentricity can be adjusted in the illumination system, in the illumination optic, in the projection system, in the projection optic, adjacent to the mask, in the mask, adjacent to a field lens of the projection exposure system, in a field plane of the illumination optic and/or the projection optic and/or adjacent to a field plane of the illumination optic and/or the projection optic. Adjusting the telecentricity at the respective sections of the projection exposure system contributes to achieving telecentric radiation at the desired locations.

Adjusting the telecentricity on a respective side means that an adjustment is made in and/or to the projection exposure system to substantially achieve telecentricity, for example telecentric radiation, at least in sections on the respective side, for example along the optical path and/or optical axis of the projection exposure system. Adjusting the telecentricity in and/or adjacent to a respective plane and/or component means that an adjustment is made in and/or to the projection exposure system to substantially achieve telecentricity, for example telecentric radiation, at least in sections in and/or adjacent to the respective plane and/or respective component, for example along the optical path and/or optical axis of the projection exposure system.

The expression “field lens” encompasses an individual optical element, for example a lens and/or a mirror, or a group of at least two individual optical elements, for example comprising at least one lens and/or at least one mirror. The expression takes account of the fact that the function of a lens can also be carried out by two or more lenses (splitting of lenses). The refractive power of this field lens can be arranged close to the field that is to say in the optical vicinity of a field plane.

According to an embodiment, the method comprises the following step: b1) conducting a pupil measurement and wherein, optionally, in step b) the telecentricity is adjusted based on the pupil measurement. By conducting a pupil measurement, the actual angle of the radiation, for example with regard to the optical axis, in a pupil of the projection exposure system can be determined. This information simplifies adjusting the telecentricity. The pupil measurement can be conducted for a pupil of the projection system and/or of the illumination system. The pupil measurement can be conducted using a pupil measurement metrology tool that measures pupil related parameters. Step b1) can take place before, during and/or after step b).

According to an embodiment, the method comprises the following step: a1) providing a substrate for microlithography, for example a silicon wafer, wherein a radiation-sensitive layer is provided at least in sections on the substrate. By providing a respective substrate a profile can be created in the radiation-sensitive layer for example. Based on this profile, in turn the telecentricity in the projection exposure system can be adjusted, for example by determining at least one critical dimension, at least one sidewall angle and/or at least one sidewall angle asymmetry of the profile created in a radiation-sensitive layer provided on the substrate and using this information for adjusting the telecentricity in the projection exposure system. The substrate can be provided in step a1) in the substrate holder of the projection exposure system. Moreover, the radiation-sensitive layer does not have to be provided directly on the substrate but can alternatively or in addition also be provided on another layer provided on the substrate.

According to an embodiment, in step b) the telecentricity is adjusted before, during and/or after the exposure of at least one radiation-sensitive layer provided on a substrate, the exposure of at least one die of a substrate, the processing of at least one substrate, the processing of at least one batch of substrates and/or the change of a production recipe. By adjusting the telecentricity at corresponding times it can be ensured that during production the deviations of a sidewall angle of a profile to be created in the radiation-sensitive layer from the intended sidewall angle, for example a sidewall angle asymmetry, can be continuously kept low. Alternatively or additionally in step b) the telecentricity is adjusted before, during and/or after the exposure of only one radiation-sensitive layer provided on a substrate, the exposure of only one die of a substrate, the processing of only one substrate and/or the processing of only one batch of substrates. The exposure of the radiation-sensitive layer provided on the substrate and/or of the die of the substrate is an exposure by the radiation provided and/or guided by the projection exposure system. A batch of substrates comprises at least two substrates, such as at least five substrates, for example at least ten substrates. Processing can comprise the steps of exposing a radiation-sensitive layer to radiation provided and/or guided by the projection exposure system, developing a radiation-sensitive layer, removing at least a part of a radiation-sensitive layer, etching the substrate, coating the substrate with a metal layer and/or polishing the substrate. Moreover, a production recipe defines a series of production steps carried out and/or production settings selected during the processing of a substrate in the projection exposure system.

According to an embodiment, the method comprises the following step: a2) providing a first optical element in the optical path of the projection exposure system, wherein, optionally, the first optical element is provided in the illumination system, in the illumination optic, in the projection system and/or in the projection optic, wherein, optionally, the first optical element is provided, for example along the optical path of the projection exposure system, adjacent to a field lens of the projection exposure system and/or adjacent to the mask, and/or wherein, optionally, the first optical element is provided, for example along the optical path of the projection exposure system, in the object plane, in the object field, adjacent to the object plane, adjacent to the object field, in the field plane, adjacent to the field plane, in the image plane, in the image field, adjacent to the image plane and/or adjacent to the image field of the illumination system, for example of the illumination optic, and/or of the projection system, for example of the projection optic. By providing a first optical element in the optical path of the projection exposure system the optical path of the projection exposure system and/or radiation guided by the projection exposure system can be adjusted, which in turn can adjust the telecentricity in the projection exposure system. By providing the first optical element in the respective locations of the exposure projection system the telecentricity can be adjusted precisely at the location where an adjustment is desired. Providing the first optical element for example adjacent to the field lens of the illumination system, adjacent to the object plane of the projection system and/or adjacent to the mask improves the telecentricity when the radiation crosses the mask, thereby contributing to a more accurate alteration of the radiation by the pattern of the mask. In this case it is for example expedient when the first optical element is provided along the optical path of the projection exposure system after the field lens of the illumination system, in front of the object plane of the projection system and/or in front of the mask, which contributes to a more accurate alteration of the radiation by the pattern of the mask. Alternatively or in addition the first optical element can be connected to the mask and/or can form a component of the mask, for example the first optical element can form the support for the pattern of the mask. The first optical element can be part of the projection exposure system, optionally of the illumination system, such as the illumination optic, and/or of the projection system, such as the projection optic.

According to an embodiment, the method comprises in step b) the telecentricity is adjusted by providing the first optical element in the optical path of the projection exposure system and/or in that in step b) the telecentricity is adjusted by adjusting the position, inclination and/or deformation of the first optical element. By adjusting the position, inclination and/or deformation of the first optical element the optical axis of the projection exposure system, the optical path of the projection exposure system and/or radiation guided by the projection exposure system can be individually adjusted to achieve the telecentricity desired in each case. The deformation of the first optical element for example includes the deformation of at least one surface of the first optical element.

The “position” of an optical element is understood to be the coordinates of the optical element or the coordinates of a measuring point provided on the optical element with respect to the x-direction, the y-direction and the z-direction, also called spatial directions. In the present context, the “orientation” of an optical element is understood to be the tilting of the optical element with respect to the three spatial directions. That is, the optical element can be tilted about the x-direction, the y-direction and/or the z-direction. This results in six degrees of freedom for the position and/or orientation of an optical element.

According to an embodiment, the first optical element has a radiation impingement surface and/or a radiation exit surface, wherein, optionally, the surface of the first optical element, for example the radiation impingement surface and/or the radiation exit surface of the first optical element, is at least in sections curved and/or straight, and/or wherein, optionally, the radiation impingement surface and/or the radiation exit surface of the first optical element is at least in sections inclined relative to the object plane of the projection system, and/or the radiation impingement surface and/or the radiation exit surface of the first optical element is at least in sections parallel with the object plane of the projection system. By providing the first optical element with a respective surface or respective surfaces, the optical path of the projection exposure system and/or radiation guided by the projection exposure system can be adjusted in an intended manner, thereby adjusting the telecentricity in the projection exposure system. This in turn can contribute to reducing deviations of a sidewall angle of a profile to be created in a radiation-sensitive layer from the intended sidewall angle. The first optical element, for example the radiation impingement surface and/or the radiation exit surface of the first optical element, can in addition be substantially completely straight or curved. For higher order adjustments of the telecentricity the surface of the first optical element, for example the radiation impingement surface and/or the radiation exit surface of the first optical element, can have at least in sections a curvature of at least first order, at least second order, at least third order, at least fourth order, at least fifth order and/or at least sixth order. The order of the curvature is the order of the polynomial function needed to describe the course of the curvature. Higher order adjustments can also be achieved by using a material for the first optical element with a respective refractive index. Moreover, the shape of the surface of the first optical element, for example the shape of the radiation impingement surface and/or of the radiation exit surface of the first optical element, is typically designed depending on the fingerprint, for example the telecentricity fingerprint, of the projection exposure system, for example of the projection optic and/or illumination optic.

The radiation impingement surface of an optical element is the surface of the respective optical element on which the radiation guided by the projection exposure systems impinges, for example enters, the optical element along the optical path of the projection exposure system, for example towards the image plane of the projection system. The radiation exit surface of an optical element is the surface of the respective optical element from which the radiation guided by the projection exposure systems exits the optical element along the optical path of the projection exposure system, for example towards the image plane of the projection system.

The fingerprint of the projection exposure system, for example of the projection optic and/or illumination optic, can be understood as a set of characteristic features, optionally image features, of the projection exposure system, for example of the projection optic and/or illumination optic.

According to an embodiment, the method comprises the following step: a3) providing a second optical element and a third optical element in the optical path of the projection exposure system, wherein, optionally, the second optical element and the third optical element are displaceable relative to each other, wherein, optionally, the second optical element and/or the third optical element is provided in the illumination system, in the illumination optic, in the projection system and/or in the projection optic, wherein, optionally, the second optical element and/or the third optical element is provided, for example along the optical path of the projection exposure system, adjacent to a field lens of the projection exposure system and/or adjacent to the mask, and/or wherein, optionally, the second optical element and/or the third optical element is provided, for example along the optical path of the projection exposure system, in the object plane, in the object field, adjacent to the object plane, adjacent to the object field, in the field plane, adjacent to the field plane, in the image plane, in the image field, adjacent to the image plane and/or adjacent to the image field of the illumination system, for example of the illumination optic, and/or of the projection system, for example of the projection optic. By providing the second optical element and the third optical element in the optical path of the projection exposure system, the optical path of the projection exposure system and/or radiation guided by the projection exposure system can be adjusted, which in turn can adjust the telecentricity in the projection exposure system. This in turn can contribute to reducing deviations of a sidewall angle of a profile to be created in a radiation-sensitive layer from the intended sidewall angle. By providing the second optical element and the third optical element displaceable relative to each other, the optical path of the projection exposure system can be adjusted thereby adjusting the telecentricity in the projection exposure system. For the second optical element and the third optical element to be displaceable relative to each other it is expedient when only the second optical element or the third optical element is mounted displaceable. However, it can be provided for that the second optical element and the third optical element are each mounted displaceable. By providing the second optical element and/or the third optical element in the respective locations of the exposure projection system the telecentricity can be adjusted precisely at the location where an adjustment is desired. Providing, optionally, the second optical element and/or the third optical element adjacent to the field lens of the illumination system, adjacent to the object plane of the projection system and/or adjacent to the mask improves the telecentricity in the radiation crossing the mask, thereby contributing to a more accurate alteration of the radiation by the pattern of the mask. Alternatively or in addition the second optical element and/or third optical element can be provided along the optical path of the projection exposure system towards the image plane of the projection exposure system after the field lens of the illumination system, in front of the object plane of the projection system and/or in front of the mask, which also contributes to a more accurate alteration of the radiation by the pattern of the mask. Alternatively or in addition the second optical element or the third optical element can be connected to the mask and/or can form a component of the mask, for example the second optical element or the third optical element can form the support for the pattern of the mask. The second optical element and/or the third optical element can be part of the projection exposure system, such as of the illumination system, for example the illumination optic, and/or of the projection system, for example the projection optic.

The designation as first, second and/or third optical element only serves to distinguish the different optical elements and does not necessarily indicate how many optical elements are provided and/or mounted in the exposure projection system.

According to an embodiment, in step b) the telecentricity is adjusted by providing the second optical element and the third optical element in the optical path of the projection exposure system, in step b) the telecentricity is adjusted by adjusting the position, inclination and/or deformation of the second optical element and/or the third optical element and/or in step b) the telecentricity is adjusted by displacing the second optical element and the third optical element relative to each other. By adjusting the position, inclination and/or deformation of the second optical element and/or the third optical element or by displacing the second optical element and the third optical element relative to each other the optical axis of the projection exposure system, the optical path of the projection exposure system and/or the radiation guided by the projection exposure system can be individually adjusted to achieve the telecentricity desired in each case. The deformation of the second optical element and/or third optical element for example includes the deformation of at least one surface of the second optical element and/or third optical element. When displacing the second optical element and the third optical element relative to each other, it can be provided that only the second optical element is displaced, that only the third optical element is displaced or that the second optical element and the third optical element are displaced.

According to an embodiment, the second optical element and/or third optical element has a radiation impingement surface and/or a radiation exit surface, wherein, optionally, the surface of the second optical element and/or third optical element, for example the radiation impingement surface and/or the radiation exit surface of the second optical element and/or the third optical element, is at least in sections curved and/or straight. By providing the second optical element and/or third optical element with a respective surface or respective surfaces the optical path of the projection exposure system and/or radiation guided by the projection exposure system can be adjusted in an intended manner, thereby adjusting the telecentricity in the projection exposure system. This in turn contributes to reducing deviations of a sidewall angle of a profile to be created in a radiation-sensitive layer from the intended sidewall angle. The second optical element and/or third optical element, for example the radiation impingement surface and/or the radiation exit surface of the second optical element and/or third optical element, can in addition be substantially completely straight or curved. For higher order adjustments of the telecentricity the surface of the second optical element and/or third optical element, for example the radiation impingement surface and/or the radiation exit surface of the second optical element and/or third optical element, can have at least in sections a curvature of at least first order, at least second order, at least third order, at least fourth order, at least fifth order and/or at least sixth order. Higher order adjustments can also be achieved by using a material for the second optical element and/or third optical element with a respective refractive index. Moreover, the shape of the surface of the second optical element and/or third optical element, for example the shape of the radiation impingement surface and/or of the radiation exit surface of the second optical element and/or third optical element, is designed depending on the fingerprint, for example the telecentricity fingerprint, of the projection exposure system, for example of the projection optic and/or illumination optic.

According to an embodiment, the method comprises the following step: a4) providing at least one aperture stop along the optical path of the projection exposure system, wherein in step b) the telecentricity is adjusted by setting the diameter of the cross-section of radiation guided by the projection exposure system and/or setting the diameter of the aperture stop in such a way that the diameter of the cross-section of the radiation guided by the projection exposure system adjacent to the aperture stop, for example impinging the aperture stop, is larger than the diameter of the aperture stop. By providing an aperture stop in the optical path of the projection exposure system the largest angles of the cone of radiation can be limited, leading to the cone of radiation having substantially the same maximum angle on all sides. This maximum angle will generally influence the sidewall angle of a profile to be created in a radiation-sensitive layer provided on a substrate. However, if the diameter of the cross-section of radiation guided by the projection exposure system is smaller than or only as large as the diameter of the aperture stop and/or the radiation is shifted relative to the optical axis, the angles of the cone of radiation are not limited, leading to a sidewall angle of a profile to be created in a radiation-sensitive layer deviating from the intended sidewall angle. In the case of the radiation shifted relative to the optical axis, for example the center of the intensity, also called center of gravity (CoG), of the radiation is shifted relative to the optical axis of the projection exposure system. The aperture stop in a pupil plane of the exposure system then cannot or only partially limit the angles of the cone of radiation, depending on the diameter of the cross-section of the radiation. A missing or incomplete limitation of the radiation by the aperture stop can lead to non-telecentric radiation in the pupil plane, in which the aperture stop is provided, and downstream of the aperture stop. By setting the diameter of the cross-section of radiation guided by the projection exposure system and/or setting the diameter of the aperture stop in the initially mentioned way, the center of the intensity may be aligned in the respective pupil plane and further downstream with the optical axis of the projection exposure system, thereby adjusting the telecentricity. In order to set the diameter of the cross-section of radiation, for example in the projection system, the numerical aperture upstream of the aperture stop, optionally in the illumination system, for example in the illumination optic, can be increased. To set the diameter of the aperture stop, optionally of the projection system, for example of the projection optic, the diameter of the aperture stop is decreased, thereby decreasing the numerical aperture, optionally of the projection system, for example of the projection optic. By increasing the numerical aperture of the illumination system and/or decreasing the numerical aperture of the projection system σ (sigma), also called the fill factor, of the projection exposure system is increased. The aperture stop can be provided in the projection system, for example in the projection optic. In step b) the telecentricity is adjusted for example adjusted by adjusting the diameter of the cross-section of radiation guided by the projection exposure system and/or adjusting the diameter of the aperture stop in such a way that the diameter of the cross-section of the radiation adjacent to the aperture stop is larger than the diameter of the aperture stop. This can help make it possible to react to changing properties of the radiation. The diameter of the cross-section of the radiation adjacent to the aperture stop can be the diameter of the cross-section of the radiation traveling towards the image plane of the projection system, for example coming from the radiation source of the projection exposure system. Moreover, the at least one aperture stop can be provided in the optical path of the projection exposure system.

The diameter of the aperture stop is understood here to mean the diameter of the opening of the aperture stop, through which opening the radiation travels along the optical path of the projection exposure system. The term “diameter” is also not limited to round or circular surfaces but encompasses surfaces of any shape.

According to an embodiment, the method comprises the following step: a5) providing at least one filter element along the optical path of the projection exposure system, wherein the filter element is positioned in a pupil plane of the projection exposure system, wherein the filter element is configured for restricting the cross-section of radiation guided by the projection exposure system and/or for absorbing radiation guided by the projection exposure system. By providing a respective filter element in the pupil plane of the projection exposure system the cross-section of radiation in the pupil plane can be restricted and/or parts of the radiation can be absorbed, which is a simple way to adjust the telecentricity. A respective filter element which is configured for restricting the cross-section of radiation guided by the projection exposure system is for example known from WO 2006/066 638 A1, which is hereby incorporated by reference. A respective filter element which is configured for absorbing radiation guided by the projection exposure system is for example known from DE 100 43 315 C1 or WO 2005/006 079 A1, which are hereby incorporated by reference. By restricting the cross-section of the radiation for example the area of the cross-section of the radiation is reduced. The filter element can be designed to be non-transmissive to the radiation provided and/or guided by the projection exposure system. With regard to absorbing the radiation provided and/or guided by the projection exposure system, optionally, only parts of the radiation and/or only up to a certain proportion of the radiation is absorbed. In other words, the filter element can be designed to be at least partially transmissive to the radiation provided and/or guided by the projection exposure system. Moreover, the filter element can be designed as a diaphragm. The filter element can be designed to comprise at least two sections, optionally with different optical properties. For example at least one section of the filter element has a, optionally substantially full, transmissivity to radiation provided and/or guided by the projection exposure system and/or at least on section of the filter element has a restricted transmissivity and/or is not transmissive to radiation provided and/or guided by the projection exposure system. Alternately or in addition the filter element can be designed as a single piece or the filter element can also be designed to comprise at least two parts. For example the filter element can comprise at least two blades. The filter element, for example the at least two blades, can be arranged rotatable and/or displaceable, for example relative to the optical path of the projection exposure system, relative to the optical axis of the projection exposure system and/or into the optical path of the projection exposure system. This contributes to an individual adjustment to achieve the telecentricity desired in each case. This contributes in turn to reducing deviations of a sidewall angle of a profile to be created in a radiation-sensitive layer from the intended sidewall angle. The filter element can be designed asymmetrically and/or be configured to restrict the radiation guided by the projection exposure system asymmetrically. This is a constructively simple way to adjust the telecentricity. Alternatively or in addition the filter element can have a first edge extending at least in sections straight, for example the opening of the filter element can have a first edge extending at least in sections straight. In this way a higher contrast as well as lower radiation dose during the exposure of a substrate can be achieved, which contributes to reducing deviations of a sidewall angle of a profile to be created in a radiation-sensitive layer from the intended sidewall angle. The opening of the filter element is in this case the opening through which radiation guided by the projection exposure system is directed and/or the opening of a diaphragm constituting the filter element. Furthermore, the filter element can have a second edge extending at least in sections straight, for example the opening of the filter element can have a second edge extending at least in sections straight. The second straight edge can be arranged opposite to the first straight edge, for example relative to the opening of the filter element. The first straight edge and/or the second straight edge can extend substantially parallel to the opening of the filter element, substantially perpendicular to the optical axis of the filter element, in the pupil plane, parallel to the pupil plane and/or substantially perpendicular to the optical path of the projection exposure system.

According to an embodiment, the method in step b) the telecentricity is adjusted by providing the filter element along the optical path of the projection exposure system, by restricting the cross-section of the radiation guided by the projection exposure system via the filter element, by absorbing the radiation guided by the projection exposure system via the filter element, by restricting the cross-section of the radiation guided by the projection exposure system asymmetrically via the filter element and/or by restricting the cross-section of the radiation guided by the projection exposure system via the filter element in such a way that in the pupil plane at least one edge of the cross-section of the radiation extends at least in sections straight. By restricting the cross-section of the radiation guided by the projection exposure system, for example asymmetrically, the center of the intensity, as mentioned above also called center of gravity (CoG), of the radiation is displaced. Thereby the telecentricity of the projection exposure system can be adjusted. This also applies for absorbing the radiation guided by the projection exposure system. By restricting the cross-section of the radiation guided by the projection exposure system in such a way that at least one edge of the cross-section of the radiation extends at least in sections straight, a higher contrast as well as lower radiation dose during the exposure of a substrate is achieved. This in turn contributes to reducing deviations of a sidewall angle of a profile to be created in a radiation-sensitive layer from the intended sidewall angle.

Alternately and/or in addition it can be provided for that step a), step a1), step a2), step a3), step a4) and/or step a5) take place before, during and/or after step b), step c) and/or step d).

A projection exposure system for microlithography can comprise: an illumination system; a projection system; a mask; a radiation source and/or an aperture stop, wherein the projection exposure system is configured to guide radiation. The projection exposure system can be configured to adjust the telecentricity in the projection exposure system using methods according to the disclosure. The explanations, details, embodiments and effects described for the method above are applicable to this projection exposure system, so that reference is made to the above explanations, details, embodiments and effects.

According to an embodiment, in step b) the aberration is applied to the radiation guided by the projection exposure system by generating at least in sections a coma aberration, for example by generating at least in sections an aberration of the Zernike polynomial Z7, at least in sections an aberration of the Zernike polynomial Z8 and/or at least in sections an aberration of the Zernike polynomial Z2, in the radiation guided by the projection exposure system. In this way radiation with a tilt in an undesired extent can be adjusted, which would otherwise lead to undesired sidewall angle asymmetry. In this case it is desirable if at least in sections an aberration of the Zernike polynomials Z7 and Z2 is generated. The generated Z2 aberration can then compensate the offset and/or overlay penalty caused by the generated Z7 aberration. The generation of the aberration of the Zernike polynomials Z7 also helps in creating a profile in the radiation-sensitive layer and/or adjusting an already created profile in the radiation-sensitive layer, which profile is formed at least in sections as trench extending at least in sections, optionally continuously, substantially in the vertical direction (vertical, i.e., perpendicular, with respect to the image plane of the projection system). Alternative or in addition it is it is desirable if at least in sections an aberration of the Zernike polynomials Z8 and Z2 is generated. The generated Z2 aberration can then compensate the offset and/or overlay penalty caused by the generated Z8 aberration. The generation of the aberration of the Zernike polynomials Z8 also helps in creating a profile in the radiation-sensitive layer and/or adjusting an already created profile in the radiation-sensitive layer, which profile is formed at least in sections as trench extending at least in sections, optionally continuously, substantially in the horizontal direction (horizontal, i.e., parallel, with respect to the image plane of the projection system). The amplitude of the Zernike polynomial Z7 applied in step b) can for example be in the range of at least 0.1 nm, such as at least 1 nm, for example at least 10 nm, for example at least 100 nm and/or at most 210 nm, such as at most 160 nm, for example at most 110 nm, for example at most 60 nm. Alternative or in addition the amplitude of the Zernike polynomial Z2 applied in step b) can for example be in the range of at least 0.1 nm, such as at least 1 nm, for example at least 10 nm, for example at least 100 nm and/or at most 350 nm, such as at most 300 nm, for example at most 200 nm, for example at most 150 nm. Alternative or in addition the amplitude of the Zernike polynomial Z8 applied in step b) can for example be in the range of at least 0.1 nm, such as at least 1 nm, for example at least 10 nm, for example at least 100 nm and/or at most 210 nm, such as at most 160 nm, for example at most 110 nm, for example at most 60 nm. Hereby a sufficient adjustment of the telecentricity can be achieved without negatively influencing the image quality too much. The at least one aberration here for example refers to at least one aberration defined as at least one Zernike polynomial (i.e., Zernike coefficient) according to the Fringe indexing scheme. The amplitude of the Zernike polynomial Z7, of the Zernike polynomial Z8 and/or of the Zernike polynomial Z2 can apply for a wavelength of the radiation, for example the radiation guided by the projection exposure system, of at least 5 nm and/or at most 500 nm, such as at least 100 nm and/or at most 350 nm, for example 248 nm, and/or for a numerical aperture (NA) of at least 0.45, such as at least 0.5, for example at least 0.55 and/or at most 0.9, for example at most 0.85, for example at most 0.8. Alternative or in addition, the Zernike polynomial Z7, the Zernike polynomial Z8 and/or of the Zernike polynomial Z2, for example the amplitude of the Zernike polynomial Z7, of the Zernike polynomial Z8 and/or of the Zernike polynomial Z2, can apply for the profile of the respective Zernike polynomial over a plurality of field points which describe the respective Zernike polynomial and which, for its part, is determined at various field points in the scanner slit of the projection optic. The scanner slit is the section of the image field of the projection optic, which is imaged at once, for example when the projection exposure system is used as a scanner. The scanner slit can be a rectangular section of the image field of the projection optic. The amplitude of the Zernike polynomial Z7, of the Zernike polynomial Z8 and/or of the Zernike polynomial Z2 can for example be the amplitude of the offset (i.e., tunable component), tilt (i.e., centrable component) and/or 3^{rd} order component of the profile of the Zernike polynomial Z7, of the Zernike polynomial Z8 and/or of the Zernike polynomial Z2 over a plurality of field points.

Certain aspects of the method for adjusting the telecentricity in a projection exposure system for microlithography and/or of the projection exposure system for microlithography are described in the following numbered disclosure clauses:
1. Method for adjusting the telecentricity in a projection exposure system (1) for microlithography comprising the following steps:
   a) providing a projection exposure system (1),
      wherein the projection exposure system (1) has an illumination system (3), a projection system (4), a mask (6), a radiation source (2) and/or an aperture stop (23),
      wherein the projection exposure system (1) is configured to guide radiation (R, R′, R″),
   b) adjusting the telecentricity in the projection exposure system (1),
      wherein, optionally, in step b) the telecentricity is adjusted by adjusting the optical path of the projection exposure system, by adjusting the optical axis (OA, OA_{IL}, OA_{PR}) of the projection exposure system (1) and/or by adjusting radiation (R, R′, R″) guided by the projection exposure system.
2. Method according to disclosure clause 1,
   characterized in that
   in step b) the telecentricity is adjusted on the object side of the illumination system (3), for example in and/or adjacent to the object plane of the illumination system (3), in step b) the telecentricity is adjusted on the image side of the illumination system (3), for example in and/or adjacent to the image plane (IP_{IL}) of the illumination system (3), in step b) the telecentricity is adjusted on the object side of the projection system (4), for example in and/or adjacent to the object plane (OP_{PR}) of the projection system (4) and/or in step b) the telecentricity is adjusted on the image side of the projection system (4), for example in and/or adjacent to the image plane (IP_{PR}) of the projection system (4).
3. Method according to disclosure clause 1 or disclosure clause 2, characterized in that
   the method comprises the following step:
   b1) conducting a pupil measurement and wherein, optionally, in step b) the telecentricity is adjusted based on the pupil measurement.
4. Method according to any one of disclosure clauses 1 to 3,
   characterized in that
   the method comprises the following step:
   a1) providing a substrate (7) for microlithography, for example a silicon wafer,
      wherein a radiation-sensitive layer (14) is provided at least in sections on the substrate (7).
5. Method according to any one of disclosure clauses 1 to 4,
   characterized in that
   in step b) the telecentricity is adjusted before, during and/or after the exposure of at least one radiation-sensitive layer (14) provided on a substrate (7), the exposure of at least one die of a substrate (7), the processing of at least one substrate (7), the processing of at least one batch of substrates (7) and/or the change of a production recipe.
6. Method according to any one of disclosure clauses 1 to 5,
   characterized in that
   the method comprises the following step:
   a2) providing a first optical element (18) in the optical path of the projection exposure system (1),
      wherein, optionally, the first optical element (18) is provided in the illumination system (3), in the illumination optic, in the projection system (4) and/or in the projection optic,
      wherein, optionally, the first optical element (18) is provided, for example along the optical path of the projection exposure system (1), adjacent to a field lens of the projection exposure system (1) and/or adjacent to the mask (6), and/or
      wherein, optionally, the first optical element (18) is provided, for example along the optical path of the projection exposure system (1), in the object plane (OP_{PR}), in the object field (OF_{PR}), adjacent to the object plane (OP_{PR}), adjacent to the object field (OF_{PR}), in the field plane, adjacent to the field plane, in the image plane (IP_{IL}, IP_{PR}), in the image field, adjacent to the image plane (IP_{IL}, IP_{PR}) and/or adjacent to the image field of the illumination system (3), for example of the illumination optic, and/or of the projection system (4), for example of the projection optic.
7. Method according to disclosure clause 6,
   characterized in that
   in step b) the telecentricity is adjusted by providing the first optical element (18) in the optical path of the projection exposure system (1) and/or in that in step b) the telecentricity is adjusted by adjusting the position, inclination and/or deformation of the first optical element (18).
8. Method according to disclosure clause 6 or 7,
   characterized in that
   the first optical element (18) has a radiation impingement surface (19) and/or a radiation exit surface (20, 20′),
      wherein, optionally, the surface of the first optical element (18), for example the radiation impingement surface (19, 19′) and/or the radiation exit surface (20, 20′) of the first optical element (18), is at least in sections curved and/or straight, and/or
      wherein, optionally, the radiation impingement surface (19, 19′) and/or the radiation exit surface (20, 20′) of the first optical element (18) is at least in sections inclined relative to the object plane (OP_{PR}) of the projection system (4), and/or the radiation impingement surface (19, 19′) and/or the radiation exit surface (20, 20′) of the first optical element (18) is at least in sections parallel with the object plane of the projection system (OP_{PR}).
9. Method according to any one of disclosure clauses 1 to 8,
   characterized in that
   the method comprises the following step:
   a3) providing a second optical element (21) and a third optical element (22) in the optical path of the projection exposure system (1),
      wherein, optionally, the second optical element (21) and the third optical element (22) are displaceable relative to each other,
      wherein, optionally, the second optical element (21) and/or the third optical element (22) is provided in the illumination system (3), in the illumination optic, in the projection system (4) and/or in the projection optic,
      wherein, optionally, the second optical element (21) and/or the third optical element (22) is provided, for example along the optical path of the projection exposure system (1), adjacent to a field lens of the projection exposure system (1) and/or adjacent to the mask (6), and/or
      wherein, optionally, the second optical element (21) and/or the third optical element (22) is provided, for example along the optical path of the projection exposure system (1), in the object plane (OP_{PR}), in the object field (OF_{PR}), adjacent to the object plane (OP_{PR}), adjacent to the object field (OF_{PR}), in the field plane, adjacent to the field plane, in the image plane (IP_{IL}, IP_{PR}), in the image field, adjacent to the image plane (IP_{IL}, IP_{PR}) and/or adjacent to the image field of the illumination system (3), for example of the illumination optic, and/or of the projection system (4), for example of the projection optic.
10. Method according to disclosure clause 9,
   characterized in that
   in step b) the telecentricity is adjusted by providing the second optical element (21) and the third optical element (22) in the optical path of the projection exposure system (1), by adjusting the position, inclination and/or deformation of the second optical element (21) and/or the third optical element (22) and/or by displacing the second optical element (21) and the third optical element (22) relative to each other.
11. Method according to disclosure clause 9 or disclosure clause 10,
   characterized in that
   the second optical element (21) and/or third optical element (22) has a radiation impingement surface (19, 19′) and/or a radiation exit surface (20, 20′),
      wherein, optionally, the surface of the second optical element (21) and/or third optical element (22), for example the radiation impingement surface (19, 19′) and/or the radiation exit surface (20, 20′) of the second optical element (21) and/or the third optical element (22), is at least in sections curved and/or straight.
12. Method according to any one of disclosure clauses 1 to 11,
   characterized in that
   the method comprises the following step:
   a4) providing at least one aperture stop (23) along the optical path of the projection exposure system (1),
      wherein in step b) the telecentricity is adjusted by setting the diameter of the cross-section (D_{R}) of radiation (R) guided by the projection exposure system (1) and/or setting the diameter (D_{A}) of the aperture stop (23) in such a way that the diameter of the cross-section (D_{R}) of the radiation (R) guided by the projection exposure system (1) adjacent to the aperture stop (23), for example impinging the aperture stop (23), is larger than the diameter (D_{A}) of the aperture stop (23).
13. Method according to any one of disclosure clauses 1 to 12,
   characterized in that
   the method comprises the following step:
   a5) providing at least one filter element (24) along the optical path of the projection exposure system (1),
      wherein the filter element (24) is positioned in a pupil plane (P) of the projection exposure system (1), and
      wherein the filter element (24) is configured for restricting the cross-section of radiation (R) guided by the projection exposure system (1) and/or for absorbing radiation (R) guided by the projection exposure system (1).
14. Method according to disclosure clause 13,
   characterized in that
   in step b) the telecentricity is adjusted by providing the filter element (24) along the optical path of the projection exposure system (1), by restricting the cross-section of the radiation (R) guided by the projection exposure system (1) via the filter element (24), by absorbing the radiation (R) guided by the projection exposure system (1) via the filter element (24), by restricting the cross-section of the radiation (R) guided by the projection exposure system (1) asymmetrically via the filter element (24) and/or by restricting the cross-section of the radiation (R) guided by the projection exposure system (1) via the filter element (24) in such a way that in the pupil plane (P) at least one edge of the cross-section of the radiation (R) extends at least in sections straight.
15. Method according to any one of disclosure clauses 1 to 14,
   characterized in that
   in step b) the telecentricity is adjusted by applying at least one aberration to the radiation (R, R′, R″) guided by the projection exposure system, and
16. Method according to disclosure clause 15,
   characterized in that
   in step b) the aberration is applied to the radiation (R, R′, R″) guided by the projection exposure system by generating at least in sections a coma aberration, for example by generating at least in sections an aberration of the Zernike polynomial Z7, at least in sections an aberration of the Zernike polynomial Z8 and/or at least in sections an aberration of the Zernike polynomial Z2, in the radiation (R, R′, R″) guided by the projection exposure system.
17. Projection exposure system (1) for microlithography comprising:
   an illumination system (3), a projection system (4), a mask (6), a radiation source (2) and/or an aperture stop (23),
   wherein the projection exposure system (1) is configured to guide radiation (R, R′, R″),
   characterized in that
   the projection exposure system (1) is constructed and arranged for adjusting the telecentricity in the projection exposure system (1) according to the method of any one of disclosure clauses 1 to 16.

Another favorable option to reduce the deviation of a sidewall angle of a profile created in the radiation-sensitive layer from the intended sidewall angle, for example a sidewall angle asymmetry, is to set a sidewall angle of a sidewall of a profile to be created in a radiation-sensitive layer provided on a substrate for microlithography.

The disclosure seeks to provide a method for reliably setting a sidewall angle of a sidewall of a profile to be created in a radiation-sensitive layer provided on a substrate for microlithography.

The method for setting a sidewall angle of a sidewall of a profile to be created in a radiation-sensitive layer provided on a substrate for microlithography can comprise the following steps: a) providing a projection exposure system, wherein the projection exposure system has an illumination system, a projection system, a mask, a radiation source and/or an aperture stop, wherein the projection exposure system is configured to guide radiation, a1) providing a substrate for microlithography, for example a silicon wafer, wherein a radiation-sensitive layer is provided at least in sections on the substrate. The explanations, details, embodiments and effects described for the method for adjusting the telecentricity in a projection exposure system for microlithography above, for example regarding the projection exposure system provided in this method, are applicable to the method for setting a sidewall angle of a sidewall of a profile to be created in a radiation-sensitive layer provided on a substrate for microlithography, so that reference is made to the above explanations, details, embodiments and effects. The following explanations, details, embodiments and effects regarding the setting of a sidewall angle of a sidewall of a profile to be created in a radiation-sensitive layer provided on a substrate for microlithography are also applicable to the already described method for adjusting the telecentricity in a projection exposure system for microlithography.

The method for setting a sidewall angle of a sidewall of a profile to be created in a radiation-sensitive layer provided on a substrate for microlithography in addition can comprise the following step: b) setting the sidewall angle of a sidewall of a profile to be created in the radiation-sensitive layer provided on the substrate. This contributes to reducing deviations of the sidewall angle of the profile to be created in the radiation-sensitive layer from the intended sidewall angle. Optionally, the profile has at least one sidewall, wherein the sidewall for example comprises the set sidewall angle.

The method for setting a sidewall angle of a sidewall of a profile to be created in a radiation-sensitive layer provided on a substrate for microlithography can furthermore comprise the step c): exposing at least a part of the radiation-sensitive layer to radiation provided and/or guided by the projection exposure system, developing at least a part of the radiation-sensitive layer and/or removing at least a part of the radiation-sensitive layer. This can contribute to creating a profile in the radiation-sensitive layer.

The method can also comprise that in step a) a second projection exposure system is provided. The second exposure system can be designed substantially identical to the initially provided projection exposure system. Optionally, in step b) the sidewall angle is set substantially in the same way as the sidewall angle in the initially provided projection exposure system.

According to a first embodiment of the method for setting a sidewall angle of a sidewall of a profile to be created in a radiation-sensitive layer provided on a substrate for microlithography, setting the sidewall angle in step b) comprises: adjusting the telecentricity in the projection exposure system according to a method disclosed herein and/or the method disclosed herein. Reference is therefore made to the above explanations, details, embodiments and effects of the method for adjusting the telecentricity in a projection exposure system for microlithography.

According to an embodiment of the method for setting a sidewall angle of a sidewall of a profile to be created in a radiation-sensitive layer provided on a substrate for microlithography, setting the sidewall angle in step b) comprises: exposing a first area of the radiation-sensitive layer to radiation guided by the projection exposure system in a first exposure, and exposing a second area of the radiation-sensitive layer to radiation guided by the projection exposure system in a second exposure. The second exposure can have the same exposure settings, for example focus, numerical aperture, illumination shape, for example illumination pupil shape, radiation wavelength and/or laser linewidth of the radiation, as the first exposure, but is not limited to it. For example, an adjustment in focus and/or numerical aperture in addition to a displacement of the mask and/or the substrate can help in realizing an adjusted and/or different sidewall angle. The radiation-sensitive layer exposed to radiation in the first exposure and the second exposure is the same radiation-sensitive layer. By exposing the radiation-sensitive layer at least twice to radiation guided by the projection exposure system it is ensured that radiation is evenly administered over the intended areas, thereby reducing deviations of a sidewall angle of a profile to be created in a radiation-sensitive layer from the intended sidewall angle due to partial or even completely insufficient exposure.

Since a second exposure of the same radiation-sensitive layer leads to a longer production time, it may be envisaged that the second exposure is performed only on a part of the substrate, wherein, optionally, the respective part of the substrate comprises at least a part of the dies arranged on the outer edge of the substrate. As the dies arranged on the outer edge of the substrate tend to have the highest deviation of the sidewall angle from the intended sidewall angle. Hereby a good compromise between production time and deviation of the angle is achieved. Moreover, it can also be provided for that setting the sidewall angle in step b) comprises: exposing a third area of the radiation-sensitive layer to radiation guided by the projection exposure system in a third exposure, exposing a fourth area of the radiation-sensitive layer to radiation guided by the projection exposure system in a fourth exposure and/or exposing a fifth area of the radiation-sensitive layer to radiation guided by the projection exposure system in a fifth exposure. In this way multiple different slopes can be created in the side wall angle profile by the multiple exposures. During the first exposure and during the second exposure the same mask can be used to alter the respective radiation guided by the projection exposure system. It also possible that during the second exposure a different mask is used to alter the respective radiation guided by the projection exposure system than during the first exposure.

According to an embodiment of the method for setting a sidewall angle of a sidewall of a profile to be created in a radiation-sensitive layer provided on a substrate for microlithography, the second area is offset at least in sections to the first area and/or the second area overlaps at least in sections with the first area. If the first area and second area are offset to one another, the sidewall angle can be adjusted in a simple manner, as this adjustment of the sidewall angle can be performed while using the same mask. Thereby also production output of the projection exposure systems is increased, as no time-consuming change of the mask used is involved. If during the first exposure the radiation did not reach the desired area of the radiation-sensitive layer and/or the radiation used during the first exposure caused an undesired sidewall angle, with the offset second exposure the radiation can reach the desired area and/or can modify the undesired sidewall angle.

According to an embodiment of the method for setting a sidewall angle of a sidewall of a profile to be created in a radiation-sensitive layer provided on a substrate for microlithography, during the second exposure the position and/or the orientation of the mask is displaced relative to the position and/or the orientation of the mask during the first exposure. Displacing the position or orientation of the mask is a simple way to achieve that the first area and the second area are offset to one another. Displacing the mask can be achieved, for example, by displacing a mask holder holding the mask.

According to an embodiment of the method for setting a sidewall angle of a sidewall of a profile to be created in a radiation-sensitive layer provided on a substrate for microlithography, during the second exposure the position and/or the orientation of the substrate is displaced relative to the position and/or the orientation of the substrate during the first exposure. Displacing the position or orientation of the substrate is a simple way to achieve that the first area and the second area are offset to one another. Displacing the substrate can be achieved, for example, by displacing a substrate holder holding the mask.

According to an embodiment of the method for setting a sidewall angle of a sidewall of a profile to be created in a radiation-sensitive layer provided on a substrate for microlithography, the focus of the radiation used during the first exposure deviates from the focus of the radiation used during the second exposure. By changing the focus of the radiation between the first exposure and second exposure the sidewall angle can be adjusted through the second exposure in a simple manner.

According to an embodiment of the method for setting a sidewall angle of a sidewall of a profile to be created in a radiation-sensitive layer provided on a substrate for microlithography the dose of the radiation used during the second exposure is lower than the dose of the radiation used during the first exposure. By providing radiation with a lower dose in the second exposure a targeted and precise adjustment can be made without unduly influencing the profile to be created in a radiation-sensitive layer in other areas.

In addition or alternatively to adjusting the dose and/or focus of the radiation between the first exposure and the second exposure the numerical aperture, illumination shape, for example illumination pupil shape, radiation wavelength and/or laser linewidth of the radiation used during the first exposure can deviate from the numerical aperture, illumination shape, for example illumination pupil shape, radiation wavelength and/or laser linewidth of the radiation used during the second exposure. Respective adjustments can help adjusting the sidewall angle.

According to an embodiment of the method for setting a sidewall angle of a sidewall of a profile to be created in a radiation-sensitive layer provided on a substrate for microlithography setting the sidewall angle in step b) comprises applying at least one aberration to the radiation guided by the projection exposure system. Here it is optionally provided for that the sidewall angle is adjusted by applying the at least one aberration in the projection optic of the projection exposure system. In this case it is for example desirable to apply the aberration along the optical path of the projection exposure system after (i.e., downstream of) the mask, before (i.e., upstream of) the image plane of the projection system and/or before (i.e., upstream of) the substrate for microlithography, for example wafer. Generation of the aberration can for example be achieved by adjusting at least one optical element, optionally the first optical element, the second optical element and/or the third optical element, of the projection exposure system. For example, the optical element can be adjusted by a deformation of the optical element, for example by using one or more actuators to exert force on one or more sides of the optical element and/or by using one or more heating elements to heat one or more selected regions of the optical element. Alternative or in addition the optical element can be adjusted by adjusting the position and/or inclination of the optical element and/or by applying strain to the optical element. The strain can for example be applied to the optical element by bending the optical element, optionally at several positions of the optical element, for example at the edge of the optical element, and/or opposing sides of the optical element. The amplitude of at least one aberration applied in step b) can for example be in the range of at least 0.1 nm, such as at least 1 nm, for example at least 10 nm, for example at least 100 nm and/or at most 400 nm, such as at most 300 nm, for example at most 200 nm, for example at most 150 nm. Hereby a sufficient adjustment of the telecentricity can be achieved without negatively influencing the image quality too much. The at least one aberration here for example refers to at least one aberration defined as at least one Zernike polynomial (i.e., Zernike coefficient) according to the Fringe indexing scheme. The amplitude of the at least one aberration can apply for a wavelength of the radiation, for example the radiation guided by the projection exposure system, of 248 nm and/or for a numerical aperture (NA) of at least 0.55 and/or at most 0.8. Alternative or in addition, the at least one aberration, for example the amplitude of the at least one aberration, optionally applies for the profile of at least one Zernike polynomial over a plurality of field points which describe the at least one aberration and which, for its part, is determined at various field points in the scanner slit of the projection optic. The scanner slit is the section of the image field of the projection optic, which is imaged at once, for example when the projection exposure system is used as a scanner. The scanner slit can be a rectangular section of the image field of the projection optic. The amplitude of at least one aberration can for example be the amplitude of the offset (i.e., tunable component), tilt (i.e., centrable component) and/or 3rd order component of the profile of the at least one aberration, for example profile of the respective Zernike polynomial, over a plurality of field points.

According to an embodiment of the method for setting a sidewall angle of a sidewall of a profile to be created in a radiation-sensitive layer provided on a substrate for microlithography it is provided for that in step b) the aberration is applied to the radiation guided by the projection exposure system by generating at least in sections a coma aberration, for example by generating at least in sections an aberration of the Zernike polynomial Z7, at least in sections an aberration of the Zernike polynomial Z8 and/or at least in sections an aberration of the Zernike polynomial Z2, in the radiation guided by the projection exposure system. In this way radiation with a tilt in an undesired extent can be adjusted, which would otherwise lead to undesired sidewall angle asymmetry. In this case it is desirable if at least in sections an aberration of the Zernike polynomials Z7 and Z2 is generated. The generated Z2 aberration can then compensate the offset and/or overlay penalty caused by the generated Z7 aberration. The generation of the aberration of the Zernike polynomials Z7 also helps in creating a profile in the radiation-sensitive layer and/or adjusting an already created profile in the radiation-sensitive layer, which profile is formed at least in sections as trench extending at least in sections, optionally continuously, substantially in the vertical direction (vertical, i.e., perpendicular, with respect to the image plane of the projection system). Alternative or in addition it is it is desirable if at least in sections an aberration of the Zernike polynomials Z8 and Z2 is generated. The generated Z2 aberration can then compensate the offset and/or overlay penalty caused by the generated Z8 aberration. The generation of the aberration of the Zernike polynomials Z8 also helps in creating a profile in the radiation-sensitive layer and/or adjusting an already created profile in the radiation-sensitive layer, which profile is formed at least in sections as trench extending at least in sections, optionally continuously, substantially in the horizontal direction (horizontal, i.e., parallel, with respect to the image plane of the projection system). The amplitude of the Zernike polynomial Z7 applied in step b) can for example be in the range of at least 0.1 nm, such as at least 1 nm, for example at least 10 nm, for example at least 100 nm and/or at most 210 nm, such as at most 160 nm, for example at most 110 nm, for example at most 60 nm. Alternative or in addition the amplitude of the Zernike polynomial Z2 applied in step b) can for example be in the range of at least 0.1 nm, such as at least 1 nm, for example at least 10 nm, for example at least 100 nm and/or at most 350 nm, such as at most 300 nm, for example at most 200 nm, for example at most 150 nm. Alternative or in addition the amplitude of the Zernike polynomial Z8 applied in step b) can for example be in the range of at least 0.1 nm, such as at least 1 nm, for example at least 10 nm, for example at least 100 nm and/or at most 210 nm, such as at most 160 nm, for example at most 110 nm, for example at most 60 nm. Hereby a sufficient adjustment of the telecentricity can be achieved without negatively influencing the image quality too much. The at least one aberration here for example refers to at least one aberration defined as at least one Zernike polynomial (i.e., Zernike coefficient) according to the Fringe indexing scheme. The amplitude of the Zernike polynomial Z7, of the Zernike polynomial Z8 and/or of the Zernike polynomial Z2 can apply for a wavelength of the radiation, for example the radiation guided by the projection exposure system, of at least 5 nm and/or at most 500 nm, such as at least 100 nm and/or at most 350 nm, for example 248 nm, and/or for a numerical aperture (NA) of at least 0.45, such as at least 0.5, for example at least 0.55 and/or at most 0.9, such as at most 0.85, for example at most 0.8. Alternative or in addition, the Zernike polynomial Z7, the Zernike polynomial Z8 and/or of the Zernike polynomial Z2, for example the amplitude of the Zernike polynomial Z7, of the Zernike polynomial Z8 and/or of the Zernike polynomial Z2, can apply for the profile of the respective Zernike polynomial over a plurality of field points which describe the respective Zernike polynomial and which, for its part, is determined at various field points in the scanner slit of the projection optic. The scanner slit is the section of the image field of the projection optic, which is imaged at once, for example when the projection exposure system is used as a scanner. The scanner slit can be a rectangular section of the image field of the projection optic. The amplitude of the Zernike polynomial Z7, of the Zernike polynomial Z8 and/or of the Zernike polynomial Z2 can for example be the amplitude of the offset (i.e., tunable component), tilt (i.e., centrable component) and/or 3^{rd} order component of the profile of the Zernike polynomial Z7, of the Zernike polynomial Z8 and/or of the Zernike polynomial Z2 over a plurality of field points.

A respective projection exposure system for microlithography can comprise: an illumination system; a projection system; a mask; a radiation source and/or an aperture stop, wherein the projection exposure system is configured to guide radiation, wherein the projection exposure system is constructed and arranged for setting the sidewall angle of a sidewall of a profile to be created in a radiation-sensitive layer provided on a substrate for microlithography according methods disclosed herein. The explanations, details, embodiments and effects described for the method for setting a sidewall angle of a sidewall of a profile to be created in a radiation-sensitive layer provided on a substrate for microlithography are applicable to this projection exposure system, so that reference is made to the above explanations, details, embodiments and effects.

Embodiments of the further disclosure are also described with the following clauses:
1. Method for setting a sidewall angle (α, α′, α″, α′″, α″″) of a sidewall (15, 15′, 15″, 15′″, 15″″) of a profile to be created in a radiation-sensitive layer (14) provided on a substrate (7) for microlithography comprising the following steps:
   a) providing a projection exposure system (1),
      wherein the projection exposure system (1) has an illumination system (3), a projection system (4), a mask (6), a radiation source (2) and/or an aperture stop (23),
      wherein the projection exposure system (1) is configured to guide radiation (R, R′, R″),
   a1) providing a substrate (7) for microlithography, for example a silicon wafer,
      wherein a radiation-sensitive layer (14) is provided at least in sections on the substrate (7),
   b) setting the sidewall angle (α, α′, α″, α′″, α″″) of a sidewall (15, 15′, 15″, 15′″, 15″″) of a profile to be created in the radiation-sensitive layer (14) provided on the substrate (7).
2. Method according to clause 1,
   characterized in that
   setting the sidewall angle (α, α′, α″, α′″, α″″) in step b) comprises:
      adjusting the telecentricity in the projection exposure system (1) according to relevant methods disclosed herein.
3. Method according to clause 1 or clause 2,
   characterized in that
   setting the sidewall angle (α, α′, α″, α′″, α″″) in step b) comprises:
      exposing a first area of the radiation-sensitive layer (14) to radiation (R) guided by the projection exposure system (1) in a first exposure, and
      exposing a second area of the radiation-sensitive layer (14) to radiation (R) guided by the projection exposure system (1) in a second exposure.
4. Method according to clause 3,
   characterized in that
   the second area is offset at least in sections to the first area and/or the second area overlaps at least in sections with the first area.
5. Method according to clause 3 or clause 4,
   characterized in that
   during the second exposure the position and/or the orientation of the mask (6) is displaced relative to the position and/or the orientation of the mask (6) during the first exposure.
6. Method according to any one of clauses 3 to 5,
   characterized in that
   during the second exposure the position and/or the orientation of the substrate (7) is displaced relative to the position and/or the orientation of the substrate (7) during the first exposure.
7. Method according to any one of clauses 3 to 6,
   characterized in that
   the focus of the radiation (R) used during the first exposure deviates from the focus of the radiation (R) used during the second exposure.
8. Method according to any one of clauses 3 to 7,
   characterized in that
   the dose of the radiation (R) used during the second exposure is lower than the dose of the radiation (R) used during the first exposure.
9. Method according to any one of clauses 1 to 8,
   characterized in that
   setting the sidewall angle (α, α′, α″, α′″, α″″) in step b) comprises:
applying at least one aberration to the radiation (R, R′, R″) guided by the projection exposure system.
10. Method according to clause 9,
   characterized in that
   in step b) the aberration is applied to the radiation (R, R′, R″) guided by the projection exposure system by generating at least in sections a coma aberration, for example by generating at least in sections an aberration of the Zernike polynomial Z7, at least in sections an aberration of the Zernike polynomial Z8 and/or at least in sections an aberration of the Zernike polynomial Z2, in the radiation (R, R′, R″) guided by the projection exposure system.
11. Projection exposure system (1) for microlithography comprising:
   an illumination system (3), a projection system (4), a mask (6), a radiation source (2) and/or an aperture stop (23),
   wherein the projection exposure system (1) is configured to guide radiation (R, R′, R″),
   wherein the projection exposure system (1) is constructed and arranged for setting the sidewall angle (α, α′, α″, α′″, α″″) of a sidewall (15, 15′, 15″, 15′″, 15″″) of a profile to be created in a radiation-sensitive layer (14) provided on a substrate (7) for microlithography according to the method of any one of clauses 1 to 10.

The disclosure as well as the further disclosure are explained in more detail below with reference to a drawing illustrating only certain embodiments.

### BRIEF DESCRIPTION OF THE DRAWINGS

FIG. 1 shows schematically an exemplary projection exposure system for microlithography.

FIG. 2 shows schematically two profiles provided in a radiation-sensitive layer in a side view.

FIG. 3A shows schematically a mask as well as incoming and outgoing radiation in a side view

FIG. 3B shows schematically a mask and a first optical element provided adjacent to the mask as well as incoming and outgoing radiation in a side view.

FIG. 3C shows schematically a mask, wherein a first optical element is incorporated into the mask as well as incoming and outgoing radiation in a side view.

FIG. 3D shows schematically a first optical element as well as incoming and outgoing radiation in a side view.

FIG. 4 shows schematically a second optical element and a third optical element as well as incoming and outgoing radiation in a side view.

FIGS. 5A to 5C show schematically an aperture stop and incoming radiation with differing cross-section diameters in a side view as well as the intensity of the respective incoming radiation.

FIGS. 6A to 6D show schematically radiation in a pupil plane as well as various filter elements arranged in the respective pupil plane in a top view.

FIGS. 7A to 7B show schematically a profile created in a radiation-sensitive layer using radiation in a side view.

FIG. 8 shows schematically radiation guided by the projection exposure system, to which radiation at least one aberration has been applied.

### DETAILED DESCRIPTION

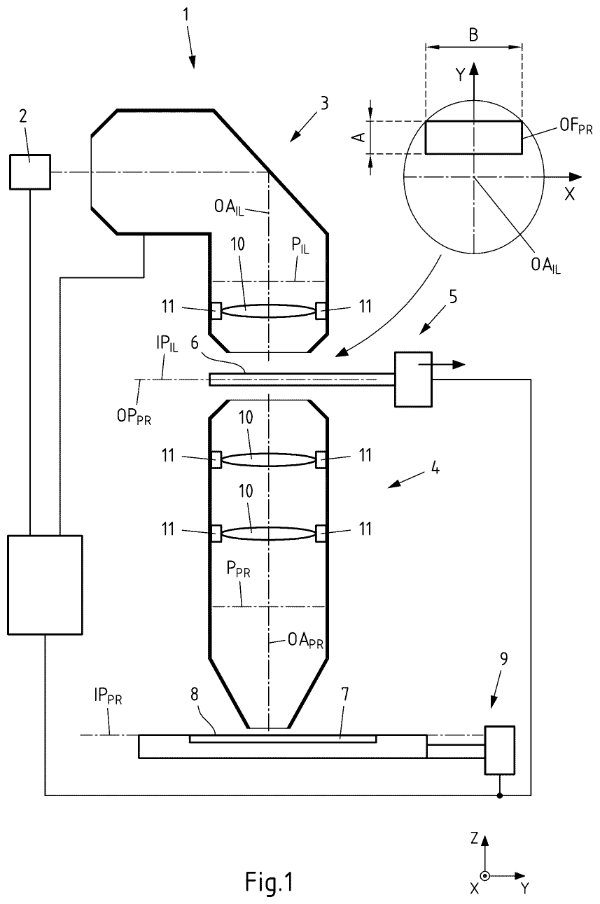

FIG. 1 shows schematically an exemplary projection exposure system 1 for microlithography, which is provided for fabricating integrated semiconductor components. The shown projection exposure system 1 includes an excimer laser as radiation source 2 having an operating wavelength of 193 nm. Other operating wavelengths, for example 157 nm, 248 nm or 365 nm, are possible. A downstream illumination system 3 generates, in its image plane IP_{IL}, a large, sharply delimited, homogeneously illuminated image field, optionally arranged off-axis with respect to the optical axis OA_{PR} of the projection system (which can be coaxial with optical axis OA_{IL}, of the illumination system) and adapted to the desired telecentric properties of the downstream projection system 4. Specifically, the exit pupil of the illumination system 3 coincides with the entrance pupil of the projection system 4 for all field points. The illumination system 3 has devices for selecting the illumination mode and, in the shown projection exposure system 1, can be changed over between conventional on-axis illumination with a variable degree of coherence, and off-axis illumination, particularly annular illumination (having a ring shaped illuminated area in a pupil plane P_{IL} of the illumination system) and dipole or quadrupole illumination. A mask holder 5 holding and manipulating a mask 6 is arranged between the exit of the illumination system 3 and the entrance of the projection system 4 such that a pattern—which pattern is part of the mask 6—of a specific layer of the semiconductor component to be produced lies in the planar object plane OP_{PR} of the projection system, the object plane OP_{PR} of the projection system coinciding with the image plane IP_{IL}, also called exit plane, of the illumination system 3. The mask holder 5—usually referred to as “reticle stage”—for holding and manipulating the mask 6 contains a scanner drive enabling the mask 6 to be moved parallel to the object plane OP_{PR} of the projection system or perpendicular to the optical axis OA_{PR} of the projection system and the optical axis OA_{IL} of the illumination system (z direction) in a scanning direction (y-direction) for scanning operation. The size and shape of the image field provided by the illumination system 3 determines the size and shape of the effective object field OF_{PR} of the projection system actually used for projecting an image, also called imaging, of a pattern of the mask 6 in the image plane IP_{PR} of the projection system. The slit-shaped effective object field OF_{PR} can have a height A parallel to the scanning direction and a width B>A perpendicular to the scanning direction and may be rectangular (as shown in the inset figure) or arcuate (ring field). An aspect ratio B/A may be in a range from B/A=2 to B/A=10, for example. The same applies for the image field.

The projection system 4 can be telecentric at the object plane OP_{PR} and image plane IP_{PR} and designed to image an image of a pattern provided by the mask 6, optionally with a reduced scale of 4:1, onto a substrate 7, for example a wafer, coated with a radiation-sensitive layer. Other reduction scales, e.g. 5:1 or 8:1, are also possible. The substrate 7 is arranged in such a way that the planar surface 8 with the radiation-sensitive layer substantially coincides with the planar image plane IP_{PR} of the projection system. The substrate 7 is held by a substrate holder 9 (also called “wafer stage”) including a drive in order to move the substrate 7, for example synchronously with the mask 6 in parallel with the latter and with reduced speed corresponding to the reduction ratio of the projection system 4. The substrate holder 9 can also include manipulators in order to move the substrate both in the Z direction parallel to the optical axis OA_{PR} of the projection system and in the X and Y directions perpendicular to the optical axis OA_{PR} of the projection system. A tilting device having at least one tilting axis running perpendicular to the optical axis OA_{PR} of the projection system can also be integrated.

The image of the pattern is formed in an effective image field of the projection system which has the same shape and aspect ratio as the effective object field OF_{PR}, but is reduced in size according to the magnification. The radiation properties within the effective image field determine the quality of the image and thereby influence the properties of the structure formed on the substrate 7.

Various different illumination settings may be set with the illumination system 3. Illumination settings may be characterized by considering the intensity distribution of an effective radiation source in a pupil plane P_{IL} of the illumination system. The pupil plane P_{PR} of the projection system can be optically conjugated to the pupil plane P_{IL} of the illumination system. Therefore, in the absence of a mask 6, a spatial intensity distribution equivalent to the intensity distribution at the radiation source may be formed in the pupil plane P_{PR} of the projection system. Where a mask 6 bearing a pattern is inserted between the illumination system 3 and the projection system 4, the intensity distribution in the pupil plane P_{PR} of the projection system also contains diffraction information corresponding to the properties of the mask 6 pattern.

The illumination system 3 as well as the projection system 4 comprise each at least one optical element 10, which can be a lens and/or a mirror. The optical elements 10 can be mounted in the projection exposure system 1 in such a way that the orientation and/or position of the optical elements 10 can be adjusted by manipulators 11. Moreover, the at least one optical element can 10 for example part of the illumination optic of the illumination system 3 and/or of the projection optic of the projection system 4.

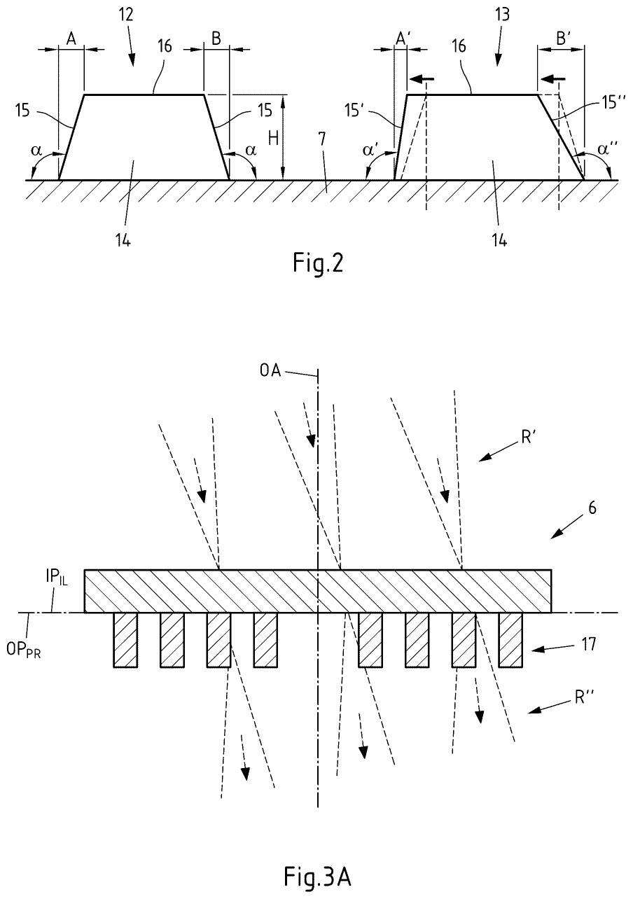

FIG. 2 shows schematically two profiles 12, 13 provided in a radiation-sensitive layer 14 in a side view. The left hand profile 12 is a reference profile 12 to be used in the layout of a so called staircase profile. For a staircase profile, usually, several profiles are stacked on top of each other in an offset arrangement, thereby forming the staircase profile. The reference profile 12 represents the optimal profile that should be created in the radiation-sensitive layer 14. The right hand profile 13 deviates from the reference profile 12 and can be called an issue profile 13. An issue profile 13 can be created in the radiation-sensitive layer 14 due variations of the telecentricity in the projection exposure system 1, due to variations in the thickness of the radiation-sensitive layer 14, due to an influence of the laser linewidth of the radiation and/or due to an influence of the slope of the radiation-sensitive layer 14, for example. The thickness of the radiation-sensitive layer 14 is shown as height H in FIG. 2. The profiles 12, 13 shown have an upper surface 16 running parallel to the straight running surface of the substrate 7. However, the substrate 7 and/or the profiles 12, 13 can also have a surface or upper surface deviating from a straight line. The reference profile 12 as well as the issue profile each comprise a pair of sidewalls 15, 15′, 15″, wherein the sidewalls 15, 15′, 15″ are each inclined relative to the substrate 7 as well as the upper surface 16 of the radiation-sensitive layer 14. In case of the reference profile 12, the sidewalls 15 are each inclined with the same sidewall angle α, with regard to the substrate 7 and the upper surface 16 of the radiation-sensitive layer 14. Moreover, the left and the right sidewalls 15 extend over the same length A, B along the substrate 7 (A=B). In the case of the issue profile 13, however, the sidewall angle α′ of the left hand sidewall 15′ deviates from the sidewall angle α″ of the right hand sidewall 15″ (α′≠α″). Furthermore, the length A′ of the left hand sidewall 15′ along the substrate 7 is shorter than the length B′ of the right hand sidewall 15″ along the substrate 7 (A′≠B′). In the shown issue profile 13 the inclination of the sidewalls 15′, 15″ is shifted on both sides to the left, as indicated by the arrows. Due to the different sidewall angles α′, α″ the issue profile 13 has a so called sidewall angle asymmetry. Such sidewall angle asymmetry can for example influence the width and the position of so called contact landing pads of 3D NAND memory. If the width and/or position of the landing pads is not sufficiently exact, overlay errors can occur during the production of 3D NAND memory. A bigger sidewall angle asymmetry therefore leads to lower yield during the 3D NAND memory production. Sidewall angle asymmetries should therefore be avoided or at least minimized.

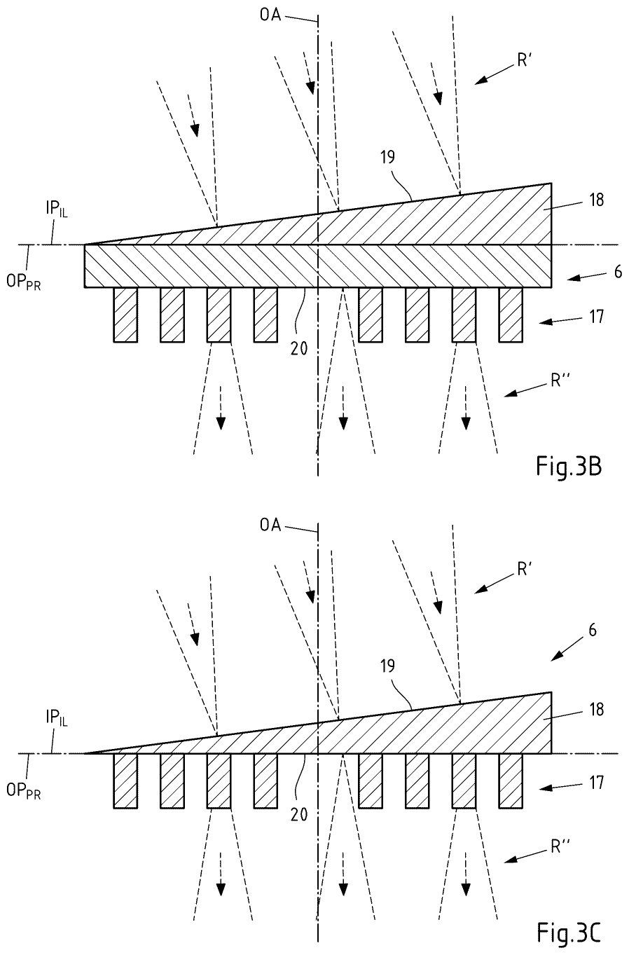

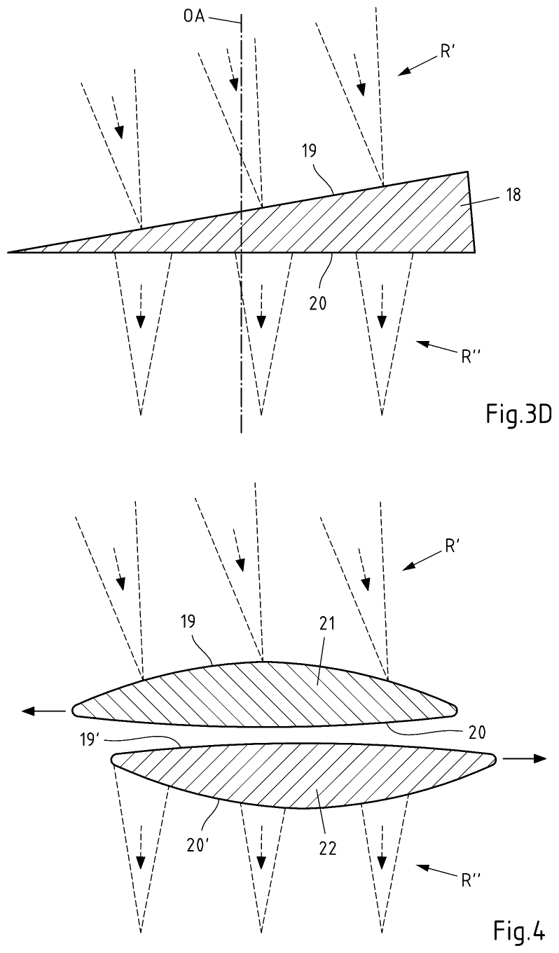

FIG. 3A shows schematically a mask 6 as well as incoming and outgoing radiation R′, R″ in a side view (In FIG. 3A and the following figures the radiation R′, R″ is shown as dashed cones, wherein the direction of travel of the radiation R′, R″ is indicated by the respective arrows shown). As can be seen the incoming radiation R′ is slightly tilted with respect to the optical axis OA, for example the optical axis OA_{IL} of the illumination system. A telecentricity error is therefore given in the illumination system 3 adjacent to the mask 6, resulting in the incoming radiation R′ impinging the mask 6 at an undesired angle. This can lead to patterning errors when the radiation passes the mask 6 and for example the pattern 17 of the mask 6. Moreover, due to the incoming radiation R′ impinging the mask 6 at an undesired angle, the outgoing radiation R″ also exits the mask 6 at an undesired angle which can lead to telecentricity error downstream of the mask 6. As a result to undesired sidewall angles α′, α″ can occur.

FIG. 3B shows schematically a mask 6 and a first optical element 18 provided adjacent to the mask as well as incoming and outgoing radiation R′, R″ in a side view. As was the case with FIG. 3A the incoming radiation R′ is slightly tilted with respect to the optical axis OA, for example the optical axis OA_{IL} of the illumination system. In order to achieve telecentricity when the incoming radiation R′ enters the mask 6, therefore also telecentricity in the image plane IP_{IL} of the illumination system and the object plane OP_{PR} of the projection system, and telecentricity downstream of the mask 6 a first optical element 18 is provided adjacent to the mask 6 in the optical path. The radiation impingement surface 19 of the first optical element 18 is inclined with regard to the image plane IP_{IL} of the illumination system and the object plane of the projection system OP_{PR} while the radiation exit surface 20 of the first optical element 18 is parallel to the image plane IP_{IL} of the illumination system and the object plane of the projection system OP_{PR} thereby adjusting the optical along which the radiation R′, R″ is transmitted as well as the radiation R′, R″. This in turn adjusts the telecentricity in the mask 6 and adjacent to the mask 6, for example in the projection system 4. Instead or in addition to the described radiation impingement surface 19 and radiation exit surface 20 other shapes and/or orientations are possible with regard to these surfaces. For example, for higher order adjustments of the telecentricity the radiation impingement surface 19 and/or the radiation exit surface 20 of the first optical element 18 can be at least in sections curved, for example with a higher order curvature.

FIG. 3C shows schematically a mask 6, wherein a first optical element 18 is incorporated into the mask 6 as well as incoming and outgoing radiation R′, R″ in a side view. The first optical element 18 of FIG. 3C is shaped as the first optical element 18 as shown in FIG. 3B. However, in FIG. 3C the first optical element 18 has been incorporated into the mask 6 and forms a component of the mask 6. The first optical element 18 for example forms the support for the pattern 17 of the mask 17. Hereby the same effects can be achieved as described with regard to FIG. 3B, however, a in a more compact design.

FIG. 3D shows schematically a first optical element 18 as well as incoming and outgoing radiation R′, R″ in a side view. The first optical element 18 of FIG. 3D is shaped as the first optical element 18 as shown in FIG. 3B. However, the optical element hast not been provided adjacent to the mask 6. An adjustment of the telecentricity can therefore be achieved at another desired location. The optical element can for example be provided further upstream of the mask 6 along the optical axis OA, for example the optical axis OA_{IL} of the illumination system, and/or the optical path of the projection exposure system 1. For example, the first optical element 18 can be provided adjacent to a field lens of the illumination system 3.

FIG. 4 shows schematically a second optical element 22 and a third optical element 23 as well as incoming and outgoing radiation R′, R″ in a side view. The radiation impingement surface 19, 19′ and the radiation exit surface 20, 20′ of both the second optical element 22 and the third optical element 23 are curved at least in sections. However, other shapes are possible with regard to the radiation impingement surfaces 19, 19′ and the radiation exit surfaces 20, 20′. As was the case with FIGS. 3A to 3C the incoming radiation R′ shown is inclined with regard to the optical axis, for example the optical axis OA_{IL} of the illumination system. In order to adjust the telecentricity the second optical element 21 and the third optical element 22 are displaceable relative to one another. In FIG. 4 the second optical element 21 and the third optical element 22 have been displaced horizontally to one another by moving the second optical element 22 to the left and the third optical element 23 to the right. However, alternatively or in addition it is possible to displace the second optical element 22 and the third optical element 23 vertically relative to one another or tilt at least one or both of the optical elements 22, 23. Moreover, it is not necessary that both optical elements 22, 23 are displaceable to one another as it can be sufficient if only one of the optical elements 22, 23 is arranged displaceable. By displacing the optical elements 22, 23 relative to one another the telecentricity can be adjusted, which in turn leads to reduced sidewall angle asymmetry.

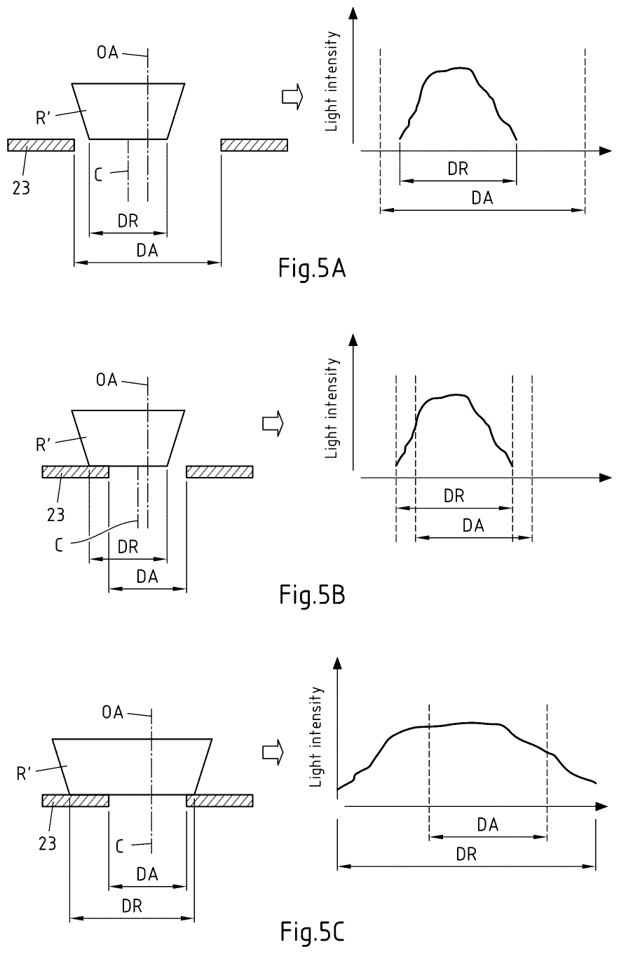

FIG. 5A to 5C show schematically an aperture stop 23 and incoming radiation R′ with differing cross-section diameters in a side view as well as the intensity of the respective incoming radiation R′. The radiation R′ shown in FIG. 5A to 5C is in each case not centered relative to the optical axis OA upstream of the aperture stop 23. In the case shown in FIG. 5A the diameter D_{A} of the aperture stop 23 is bigger than the diameter D_{R} of the cross-section of the radiation R′ (D_{A}>D_{R}). As a result the entire radiation R′ can pass the aperture stop 23 . . . . The center of intensity C, also called center of gravity (COG), of the radiation R′ downstream of the aperture stop 23 is therefore shifted with regard to the optical axis OS and thus offset to the optical axis OA. As a result telecentricity errors can occur in the pupil plane as well as downstream of the aperture stop 23.

In the case shown in FIG. 5B the diameter D_{A} of the aperture stop 23 is as big as the diameter D_{R} of the cross-section of the radiation R′ (D_{A}=D_{R}). However, as the radiation R′ upstream of the aperture stop 23 is not centered relative to the optical axis OA, the aperture stop 23 can only partially limit the angles of the cone of radiation R′. As a result the center of intensity C of the radiation R′ downstream of the aperture stop 23 is shifted with regard to the optical axis OS, leading to telecentricity errors in the pupil plane as well as downstream of the aperture stop 23.

In the case shown in FIG. 5C the diameter D_{A} of the aperture stop 23 is as smaller than the diameter D_{R} of the cross-section of the radiation R′ (D_{A}<D_{R}). As a result the radiation R′ upstream of aperture stop 23 “overfills” the apertures top 23. The apertures stop 23 can thereby limit the angles of the cone of radiation around the entire circumference of the opening of the aperture stop 23 and as a result the outer edges of the radiation R′ upstream of the aperture stop 23 are hindered from passing the aperture stop 23. The center of intensity C of the radiation R′ will thereby be aligned in the respective pupil plane and downstream of the aperture stop 23 with the optical axis OA of the projection exposure system 1, thereby adjusting the telecentricity. In addition, this leads to a reduced sidewall angle asymmetry. In order to overfill the aperture stop 23 one can set or adjust the diameter D_{R} of the cross-section of the radiation R′ and/or set or adjust the diameter D_{A} of the aperture stop 23.

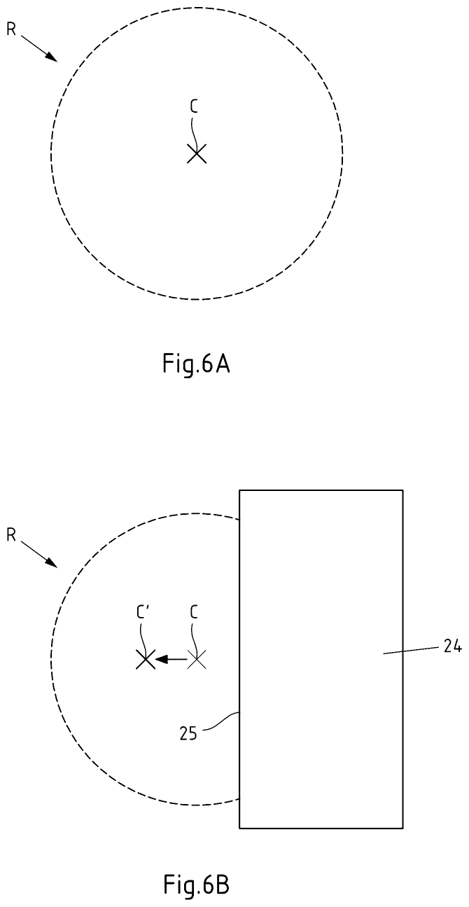

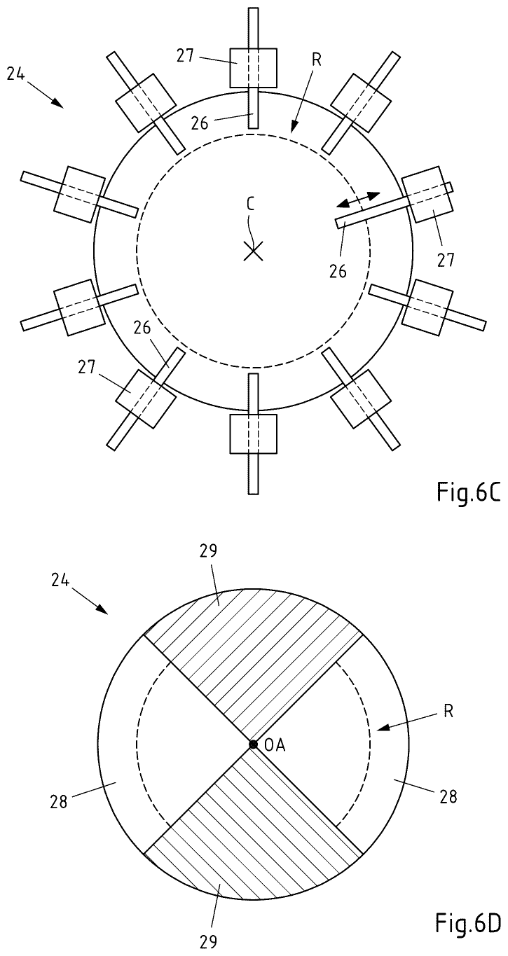

FIG. 6A to 6D show schematically radiation R in a pupil plane as well as various filter elements 24 arranged in the respective pupil plane P in a top view. FIG. 6A shows for reference schematically the cross-section of unobstructed radiation R in a top view. The cross-section of the radiation R shown is located in and parallel to a pupil plane P of the projection exposure system 1, for example a pupil plane P_{IL} of the illumination system 4. The center of intensity C, also called center of gravity (COG), of the radiation R is located in the center of the cross-section of the radiation R.

In FIG. 6B a filter element 24 has been inserted into the radiation R in the pupil plane P thereby restricting the cross-section of the radiation R. In the case shown the filter element is not transmissive to radiation R provided and/or guide by the projection exposure system. As a result of this restriction of the cross-section of the radiation R the center of the intensity C′ of the radiation R shifted. Moreover, the restriction of the cross-section of the radiation R contributes in adjusting the telecentricity due to the shift of the center of the intensity C′ of the radiation R. The filter element 24 shown has a straight edge 25 resulting in the cross-section of the radiation R having a straight edge in the pupil plane P as well. Moreover, due to the position and shape of the filter element 24, the filter element 24 restricts the radiation R in the pupil plane P asymmetrically. However, other shapes for the edge 25 of the filter element 24 as well as other ways to restrict the radiation R in the pupil plane P, for example symmetrically, are possible. Moreover, the filter element 24 may consist of at least two parts, for example two blades. The two blades can then be used, for example, to restrict opposing sides of the radiation R.

FIG. 6C shows another filter element 24 provided in the pupil plane P comprising several blades 26. The blades 26 can be displaced individually into radiation R parallel to and in the pupil plane P to restrict the cross-section of the radiation R (as indicated by the arrow in FIG. 6C). In order to displace the blades 26, several actuators 27 are provided. This allows for a precise and targeted restriction of the cross-section of the radiation R and therefore a precise and targeted shift of the center of the intensity C′ of the radiation R.

FIG. 6D shows yet another filter element 24 provided in the pupil plane P comprising four sections 28, 29. Two of the four sections 28 are substantially fully transmissive to the radiation R provided and/or guided by the projection exposure system 1, while the remaining two sections 29 have a restricted transmissivity to the radiation R provided and/or guided by the projection exposure system 1. The filter element 24 is provided rotatable relative to the optical axis OA of the projection exposure system, for example the optical axis OA_{IL} of the illumination system, thereby enabling adjustments to the radiation R.

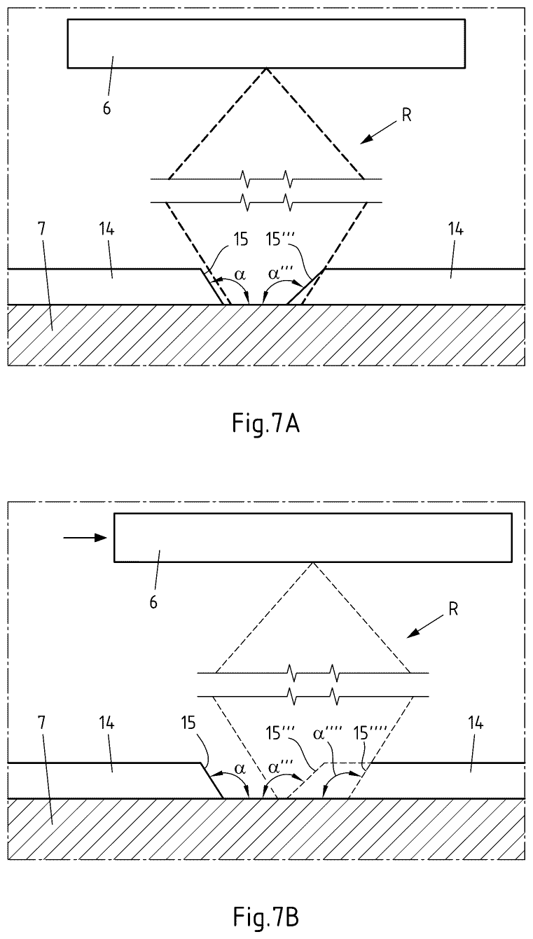

FIG. 7A to 7B show schematically a profile created in a radiation-sensitive layer 14 using radiation R in a side view. The radiation R shown is guided by the projection exposure system 1 from the (schematically shown) mask 6 towards the substrate 7. For the sake of clarity the structure of the projection system 4, for example the optical elements 10 provided therein, were omitted in the drawing as indicated by the zig-zagged lines. Moreover, for illustrative purposes the parts of the radiation-sensitive layer 14 impinged by the radiation R during a first exposure (FIG. 7A) and a second exposure (FIG. 7B) are omitted. In the present case it is not intended that the radiation-sensitive layer 14 is developed between the first exposure and the second exposure.

The surface of the radiation-sensitive layer 14 shown in FIGS. 7A and 7B runs parallel to the straight running surface of the substrate 7. However, the substrate 7 and/or the radiation-sensitive layer 14 can also respectively have a surface deviating from a straight line.

In FIG. 7A the profile created in the radiation-sensitive layer 14 is designed for the layout of a staircase profile. On the left hand side the sidewall 15 is inclined with an intended sidewall angle α. However, on the right hand side the sidewall 15′″ is inclined with an incorrect sidewall angle α′″. This can be for example caused by a telecentricity error in the projection exposure system 1, by a variation in the thickness of the radiation-sensitive layer 14, due to an influence of the laser linewidth of the radiation R and/or due to an influence of the slope of the radiation-sensitive layer 14. In order to correct this deviation of the sidewall angle α′″ a second exposure is conducted.

As shown in FIG. 7B, the mask 6 was displaced for the second exposure in order to displace the radiation R. Instead or in addition to displacing the mask 6, also the substrate 7 can be displaced. As a result of the displacement of the mask 6 the area of the radiation sensitive layer 14 exposed to the radiation R during the second exposure is offset with regard to the area of the radiation sensitive layer 14 exposed to the radiation R during the first exposure (The offset between the two areas is shown disproportionately large in FIG. 7B to better illustrate it). In addition, during the second exposure also the focus of the radiation R used was adjusted compared to the focus of the radiation R used during the first exposure. Moreover, the dose of the radiation R used during the second exposure was reduced compared to the dose of the radiation R used during the first exposure (The dose reduction is indicated in FIGS. 7A and 7B by the different thickness of the dashed lines). However, an adjustment of the dose and/or the focus of the radiation R is not necessary. Due to the second exposure the profile created in the radiation-sensitive layer 14 was adjusted, so that the right hand sidewall 15″″ now has the intended sidewall angle α″″.

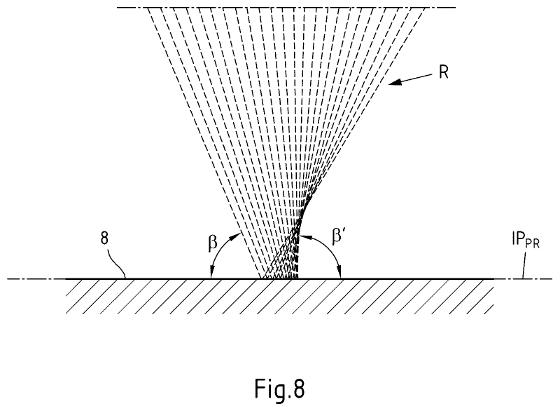

FIG. 8 shows schematically radiation R guided by the projection exposure system 1, to which radiation R at least one aberration has been applied. A coma aberration, in the case shown an aberration of the Zernike polynomial Z7, has been applied to the radiation R. In the case shown the aberration was applied to the radiation R in the projection system 4 of the projection exposure system 1. As a result of the applied aberration the incident angle β, β′ of the radiation R impinging on the substrate surface 8 located in the image plane of the projection system IP_{PR}, the telecentricity of the radiation R and/or the sidewall angle α, α′, α″, α′″, α″″ of the profile to be created in the radiation-sensitive layer 14 is adjusted and/or set. In order to compensate a possible offset of the radiation R and/or overlay error induced by the applied aberration of the Zernike polynomial Z7, it is also desirable to apply in addition an aberration of the Zernike polynomial Z2. In the case shown in FIG. 8 the incident angles β, β′ on opposing sides of the wavefront of the radiation R differ from one another, for example around the substrate surface 8 located in the image plane of the projection system IP_{PR}. This for example helps setting the desired sidewall angle α, α′, α″, α′″, α″″ of the profile to be created in the radiation-sensitive layer 14.

In FIG. 8 the effect of the aberration on the radiation R, for example the resulting incident angles β, β′ of the radiation R, has been exaggerated to better illustrate the effect of the applied aberration.

### LIST OF REFERENCE SIGNS

1 projection exposure system
2 radiation source
3 illumination system
4 projection system
5 mask holder
6 mask
7 substrate
8 substrate surface
9 substrate holder
10 optical element
11 manipulator
12 reference profile
13 issue profile
14 radiation-sensitive layer
15, 15′, 15″, 15′″, 15″″ side wall
16 upper surface
17 pattern
18 first optical element
19, 19′ radiation impingement surface
20, 20′ radiation exit surface
21 second optical element
22 third optical element
23 aperture stop
24 filter element
25 edge of the filter element
26 blade
27 actuator
28 fully transmissive section
29 section with restricted transmissivity
A, A′ length
B, B′ length
C, C′ center of intensity
D_{A} diameter of the aperture stop
D_{R} diameter of the cross-section of the radiation
H height
IP_{IL} image plane of the illumination system
IP_{PR} image plane of the projection system
OA optical axis
OA_{IL} optical axis of the illumination system
OA_{PR} optical axis of the projection system
OF_{PR} object field of the projection system
OP_{PR} object plane of the projection system
P pupil plane
P_{IL} pupil plane of the illumination system
P_{PR} pupil plane of the projection system
R, R′, R″ radiation
α, α′, α″, α′″, α″″ sidewall angle
β, β′ incident angle

1. A method of adjusting a microlithography projection exposure system which comprises an illumination system and a projection system, the microlithography projection exposure system configured to guide radiation, the method comprising:
adjusting a telecentricity in the microlithography projection exposure system by adjusting an optical path of the microlithography projection exposure system, adjusting an optical axis of the microlithography projection exposure system and/or by adjusting the radiation,
wherein adjusting the telecentricity in the microlithography projection exposure system comprises adjusting a telecentricity in the illumination system.

2. The method of claim 1, wherein the telecentricity is adjusted based on a pupil measurement of the microlithography projection exposure system.

3. The method of claim 2, further comprising making the pupil measurement of the microlithography projection exposure system.

4. The method of claim 1, wherein the telecentricity is adjusted on:
an object side of the illumination system;
an image side of the illumination system;
on an object side of the projection system; and/or
on an image side of the projection system.

5. The method of claim 1, wherein the telecentricity is adjusted:
in or adjacent an object plane of the illumination system;
in or adjacent an image plane of the illumination system;
in or adjacent an object plane of the projection system; and/or
in or adjacent an image plane of the projection system.

6. The method of claim 1, further comprising using the microlithography projection exposure apparatus to expose a radiation-sensitive material of a substrate to radiation, wherein the telecentricity is adjusted before, during and/or after exposing the substrate to the radiation.

7. The method of claim 1, wherein adjusting the telecentricity comprises adjusting a position, an inclination and/or a deformation of a first optical element, and the first optical element is in an optical path of the radiation in the microlithography projection exposure apparatus.

8. (canceled)

9. (canceled)

10. The method of claim 7, wherein the first optical element is adjacent to a field lens in the microlithography projection exposure system, and/or wherein the first optical element is adjacent to a mask in in the microlithography projection exposure system.

11. The method of claim 7, wherein the first optical element is in or adjacent:
an object plane of the projection system;
an object field of the projection system;
a field plane of the microlithography projection exposure apparatus; and/or
an image plane of the microlithography projection exposure apparatus.

12. The method of claim 7, wherein the first optical element comprises a radiation impingement surface and a radiation exit surface, and:
at least a portion of the radiation impingement surface is inclined relative to an object plane of the projection system;
at least a portion of the radiation exit surface is inclined relative to the object plane of the projection system;
at least a portion of the radiation impingement surface is parallel to the object plane of the projection system; and/or
at least a portion of the radiation exit surface is parallel to the object plane of the projection system.

13. The method of claim 7, wherein:
the microlithography projection exposure apparatus further comprises second and third optical elements in the optical path of the radiation; and
the second and third optical elements are displaceable relative to each other.

14. The method of claim 13, wherein the second optical element and/or the third optical element is/are:
adjacent a field lens of the microlithography projection exposure system; and/or
adjacent to a mask in the microlithography projection exposure system.

15. The method of claim 13, wherein the second optical element and/or the third optical element is/are in or adjacent:
an object plane of the projection system;
an object field of the projection system;
a field plane of the microlithography projection exposure apparatus; and/or
an image plane of the microlithography projection exposure apparatus.

16. The method of claim 13, wherein adjusting the telecentricity comprises adjusting:
a position, an inclination and/or deformation of the second optical element;
a position, an inclination and/or deformation of the third optical element;
displacing the second and third optical elements relative to each other.

17. The method of claim 1, wherein adjusting the telecentricity comprises setting a diameter of a cross-section of the radiation.

18. (canceled)

19. (canceled)

20. The method of claim 19, wherein the filter element absorbs some of the radiation to restrict the cross-section of the radiation.

21. The method of claim 19, wherein:
the filter element asymmetrically filters the radiation; and/or
the filter element guides the radiation so that, in the pupil plane, at least sections of an edge of the cross-section of the radiation are straight.

22. The method of claim 1, wherein the telecentricity is adjusted by applying an aberration to the radiation.

23. (canceled)

24. A method for setting a sidewall angle of a sidewall of a profile to be created in a radiation-sensitive layer supported by a substrate using radiation guided by a projection exposure apparatus which comprises an illumination system, a projection system and a mask, the method comprising:
setting the sidewall angle of the sidewall of the profile to be created in the radiation-sensitive layer supported by the substrate.

25. The method of claim 24, wherein setting the sidewall angle comprises adjusting a telecentricity in the microlithography projection exposure system by adjusting an optical path of the microlithography projection exposure system, adjusting an optical axis of the microlithography projection exposure system and/or by adjusting the radiation, and
wherein adjusting the telecentricity in the microlithography projection exposure system comprises adjusting a telecentricity in the illumination system.

26.-33. (canceled)
